(19) United States
(12) Patent Application Publication
(10) Pub. No.: US 2025/0298077 A1
(43) Pub. Date: Sep. 25, 2025

(54) Antenna device and an automated test equipment with a ridged blind mating waveguide flange

(71) Applicants: José MOREIRA, Stuttgart (DE); Advantest Corporation, Tokyo (JP)

(72) Inventors: José MOREIRA, Stuttgart (DE); Natsuki SHIOTA, Tokyo (JP); Daniel LAM, San Jose, CA (US); Yuchang LIU, San Jose, CA (US)

(21) Appl. No.: 19/229,548

(22) Filed: Jun. 5, 2025

Related U.S. Application Data
(63) Continuation of application No. PCT/EP2022/087139, filed on Dec. 20, 2022.

(51) Int. Cl. G01R 31/302; G01R 1/067; H01Q 13/02

(52) U.S. Cl. CPC G01R 31/3025; G01R 1/06772; H01Q 13/0266

(57) ABSTRACT

An antenna device for establishing a wireless coupling to a device under test has an antenna structure, and a first blind mating waveguide flange coupled to the antenna structure, wherein the first waveguide flange comprises a ridged waveguide structure with at least two ridges.

### CROSS-REFERENCE TO RELATED APPLICATION

This application is a continuation of copending International Application No. PCT/EP2022/087139, filed Dec. 20, 2022, which is incorporated herein by reference in its entirety.

### TECHNICAL FIELD

Embodiments according to the invention relate to an antenna device and an automated test equipment, in particular comprising a ridged structure.

Embodiments according to the invention relate to a blind mating dual-ridge and quad-ridge waveguide interface for mmWave automated test equipment high volume production testing

### BACKGROUND OF THE INVENTION

Increasingly higher frequencies are used for modern devices such as mobile phones. For example, 5G NR (new radio) technology uses two frequency ranges, wherein a “second” frequency range FR2 may employ a bandwidth of, for example, 24 to 53 GHz, which spans a bandwidth of over an octave.

Standard commercial waveguide geometries are limited in the frequency rage they can support. In some cases, two different waveguide geometries would need to be used to cover the 5G frequency range of 24 to 53 GHz, requiring two separate insertions in a volume production testing, increasing costs of the test. Coaxial connectors usually cannot support the number of insertions required in most high volume manufacturing productions (e.g., 1 million mating cycles or more).

Therefore, there is a need for an antenna device that improves a compromise between testing efficiency and bandwidth.

### SUMMARY

According to an embodiment, an antenna device for establishing a wireless coupling to a device under test may have an antenna structure; and a first blind mating waveguide flange; coupled to the antenna structure, wherein the first waveguide flange has a ridged waveguide structure with at least two ridges.

According to another embodiment, an automated test equipment may have the antenna device as mentioned above, and a test fixture with a second blind mating waveguide flange configured to be coupled to the first waveguide flange of the antenna device, wherein the second waveguide flange has a ridged waveguide structure that mates with the ridged waveguide structure of the first waveguide flange.

According to another embodiment, a method for testing a device under test may have the steps of establishing a coupling between a device under test and an automated test equipment using an antenna device, wherein the antenna device has an antenna structure, and a first blind mating waveguide flange coupled to the antenna structure, wherein the first waveguide flange has a ridged waveguide structure with at least two ridges, and coupling the first waveguide flange to a second blind mating waveguide flange of an automated test equipment.

An embodiment according to the invention is directed at an antenna device for establishing a wireless coupling to a device under test, comprising an antenna structure (e.g. an antenna element; e.g., a measurement antenna), and a first blind mating waveguide flange coupled to the antenna structure, wherein the first waveguide flange comprises a ridged waveguide structure with at least two ridges.

It has been recognized that the first waveguide flange enables a fast and robust docking with a test fixture adapted to carry a device under test. The ridge structure allows for an increased bandwidth range (e.g., 24 to 53 GHz), allowing a test device (device under test, DUT) that operates over such a large bandwidth to be tested with only the claimed antenna device (e.g., instead of using multiple antenna devices that collectively cover the bandwidth of the device under test). Since the waveguide flange is configured for blind mating, docking can be performed faster (when compared to non blind mating connectors) and optionally automated. Using a blind mating waveguide flange also simplifies properly aligning the first waveguide flange with a waveguide flange of the test fixture or with a waveguide flange that is, for example, attached to a test head of an automated test equipment or to a loadboard, thus reducing the risk of having a bad connection between an automated test equipment and the antenna device. To conclude, since the first waveguide flange is configured to be blind mating, the risk of misalignment is reduced, and a good signal transmission over a very wide frequency range can be achieved (e.g. with low loss and/or low reflection). The first waveguide flange improves a compromise between mating reliability and bandwidth.

The antenna device may form or may be part of a blind mating interconnect design based on a dual-ridge and/or quad-ridge waveguide design. Such a blind mating interconnect may be useful for automated test equipment (ATE) applications, for example, because of the need to automatically undock the test fixture where a device under test (DUT) resides.

According to an embodiment, a face of the first waveguide flange comprises a choke structure. The choke structure may improve electromagnetic continuity between the first blind mating waveguide flange and a second waveguide flange coupled thereto. In other words, the choke structure may help to reduce an impact of parasitic gaps at the waveguide flange. As a result, return loss may be increased, transmission loss may be reduced and the reliability of a coupling is improved.

According to an embodiment, at a face of the first waveguide flange, an inner wave-guiding structure of the first waveguide flange (e.g. a double-ridged hollow wave-guiding structure) may be surrounded by a recess (e.g. a rectangular recess; e.g. a trench-like recess) (e.g. with a conductive structure at least partially between inner wave-guiding structure and the recess). The recess may form the choke structure, be part of the choke structure or be provided additionally to the choke structure. The recess may, for example, have a depth of a quarter of a largest wavelength (e.g., 12.5 mm, which corresponds to 24 GHz), centre wavelength (e.g., 7.8 mm, which corresponds to 38.5 GHz) or shortest wavelength (e.g., 5.7 mm, which corresponds to 53 GHz) of a spectrum to be transmitted by the first waveguide flange (e.g. within a tolerance of +/−10% or +/−5%). A distance between the recess and at least one inner surface of the first waveguide flange may, for example, be a quarter of a largest wavelength (e.g., 12.5 mm, which corresponds to 24 GHz), centre wavelength (e.g., 7.8 mm, which corresponds to 38.5 GHz) or shortest wavelength (e.g., 5.7 mm, which corresponds to 53 GHz) of a spectrum to be transmitted by the first waveguide flange (e.g. within a tolerance of +/−10% or +/−5%). Accordingly, the structure may provide good electrical (electromagnetic) transmission characteristics and may have a reduced sensitivity to mechanical tolerances and/or surface imperfections.

The recess may form a resonant short-circuit stub, which can establish a high impedance (e.g. at a transition between the recess and the coupling recess). This high impedance may be transformed into a low impedance in a region between the recess and the waveguide (i.e. within the coupling recess). Accordingly, a low or even very low impedance may be achieved at an inner boundary of the coupling recess. The structure may therefor reduce return loss across the first waveguide flange and a second waveguide flange coupled thereto.

According to an embodiment, the inner wave-guiding structure of the first waveguide flange comprises a substantially rectangular cross-section, wherein two ridges (e.g. two ridges having a substantially rectangular cross-section) are arranged at two opposite sides (e.g. boundaries) (e.g. at opposite longer sides or opposite longer boundaries) of the substantially rectangular cross-section of the inner wave-guiding structure, and wherein boundaries of the inner wave-guiding structure comprise coupling recesses in regions of two further sides (e.g. boundaries) (e.g. in regions of opposite shorter sides or opposite shorter boundaries) of the substantially rectangular cross-section of the inner wave-guiding structure, to allow for a coupling between the inner wave-guiding structure and the recess surrounding the inner wave-guiding structure.

The coupling recesses may, for example, present a low impedance to the inner wave-guiding structure, which helps to reduce discontinuities and to obtain good electrical (electromagnetic) transmission characteristics.

According to an embodiment, the first waveguide flange comprises a removable face structure (e.g. a structure comprising a straight waveguide portion) that comprises a face of the first waveguide flange.

The removable face structure can be exchanged or removed (e.g. for repairing) after being worn down by repeated coupling procedures. The wear is therefore limited to a comparatively small structure (e.g. to the removable face structure) that can be replaced and/or repaired. This avoids changing the antenna device, which commonly is the more expensive component. Furthermore, there is no need to use any special plating on the antenna.

According to an embodiment, the removeable face structure is at least partially plated with a plating that comprises at least one of nickel and gold. The plating may comprise an outer gold plating (comprising gold or being formed of gold) and an inner nickel plating (comprising nickel or being formed from nickel).

It has been recognized that a plating comprising gold is stable for many coupling processes (e.g., over a million coupling processes) and that nickel improves wear resistance (e.g., as barrier metal).

According to an embodiment, the plating comprises a gold layer with a thickness in a range of 1.5 μm to 2.5 μm and a nickel layer with a thickness in a range of 0.5 μm and 1.2 μm.

It has been recognized that such dimensions improve a compromise between wear resistance and material costs. Also, it has been found that such dimensions bring along good electrical characteristics.

According to an embodiment, the first waveguide flange has a substantially rectangular cross section with two (comparatively) wide inner surfaces and two (comparatively) narrow inner surfaces that are narrower than the wide inner surfaces, wherein a first and second ridge of the ridged waveguide structure extend towards each other from the wide inner surfaces (such that a double-ridged waveguide structure is formed). The first and second ridge may, for example, have at least essentially the same dimensions. The first and second ridge may respectively be arranged on a centre axis of each of the wide inner surfaces.

Such an arrangement of the first and second ridge can provide a larger bandwidth compared to a similar waveguide without ridges. The double ridged waveguide may provide a bandwidth that spans over an octave (i.e. that spans more than an octave) (e.g., a largest wavelength of the bandwidth is larger than twice the smallest wavelength of the bandwidth). Accordingly, the waveguide can transmit signals which allow for a testing of broadband devices (DUTs).

According to an embodiment, the narrow inner surfaces have a width in a range of 2.4 mm and 2.7 mm or in a range between 2.5 mm and 2.6 mm, wherein the wide inner surfaces have a width in a range of 5.3 mm to 5.7 mm or in a range between 5.4 mm and 5.6 mm, or in a range between 5.44 mm and 5.54 mm, wherein a width of a gap between the first ridge and the second ridge is in a range between 1.0 mm and 1.2 mm or in a range between 1.04 mm and 1.14 mm, and wherein a width of the first ridge and of the second ridge is in a range between 1.3 mm and 1.5 mm or in a range between such as 1.32 mm and 1.42 mm.

It has been recognized that such dimensions provide a waveguide flange with a bandwidth spanning between 24 GHz to 53 GHz that has an improved compromise between insertion loss (e.g., smaller than 1 db) and return loss (e.g., above 20 db). Such a waveguide flange is therefore particularly well suited for use in the 5G spectrum (e.g., the frequency range 2).

According to an embodiment, a ratio between a width (e.g. a total width) of the wide inner surface (e.g. measured in a cross-section that is perpendicular to an axis of the wave guide) and a width (e.g. a total width) of the narrow inner surface (e.g. measured in a cross-section that is perpendicular to an axis of the wave guide) is 2.15, with a tolerance of +/−10 percent (or within a tolerance of +/−5%), and wherein a ratio between a width (e.g. a total width) of the wide inner surface (e.g. measured in a cross-section that is perpendicular to an axis of the wave guide) and a width of a gap between the first ridge and the second ridge (e.g. measured in a cross-section that is perpendicular to an axis of the wave guide) is 5.04, with a tolerance of +/−10 percent (or within a tolerance of +/−5%), and a ratio between a width (e.g. a total width) of the wide inner surface (e.g. measured in a cross-section that is perpendicular to an axis of the wave guide) and a width of the first ridge and of the second ridge (e.g. measured in a cross-section that is perpendicular to an axis of the wave guide) is 4.01, with a tolerance of +/−10 percent (or within a tolerance of +/−5%).

A waveguide flange with such dimensions can have a bandwidth that exceeds an octave and provides an improved compromise between insertion loss and return loss (e.g. at a transition).

According to an embodiment, the first waveguide flange has a substantially rectangular (e.g. square) cross section with four inner surfaces (e.g. of equal width), wherein the ridged waveguide structure comprises four ridges, each of the four ridges extending from a respective one of the four inner surfaces towards a central axis of the first waveguide flange (such that a quad-ridged waveguide structure is formed).

It has been found that four ridges can be advantageously used in dual polarized applications which comprise a high bandwidth. For example, the first waveguide flange may be coupled (e.g., at an end of a quad-ridged waveguide opposite to the flange) to two double-ridged waveguides. The two double-ridged waveguides allow coupling two different polarizations into a quad-ridged waveguide that extends towards the first waveguide flange. The usage of a quad-ridge waveguide may improve saving real-estate for a dual polarized application. Moreover, only a single blind-mating waveguide connection is used to transmit signals associated with two polarizations when using a waveguide structure having four ridges. This significantly reduces the mechanical requirements in some cases.

According to an embodiment, the inner surfaces have a width in a range of 5.1 mm and 5.3 mm, or in a range between 5.15 mm and 5.25 mm (such that, for example, a spacing between opposite inner surfaces is in a range between 5.1 mm or in a range between 5.15 mm and 5.25 mm when leaving the ridges unconsidered), wherein each of the four ridges extends towards a central axis of the ridged waveguide structure in a range of 0.9 mm to 1.1 mm, or in a range between 0.95 to 1.05 mm, and wherein each of the four ridges has a width in a range of 1.1 mm to 1.3 mm, or in a range between 1.15 mm to 1.25 mm.

It has been recognized that such dimensions allow for a wide bandwidth (e.g. a wide mono-mode bandwidth) (e.g., above 24 GHz) while providing good transmission characteristics (e.g. in terms of scattering parameters S_{1,2}, S_{2,1} and S_{1,1}, S_{2,2}) within the bandwidth.

According to an embodiment, the inner surfaces comprise equal widths within a tolerance of +/−10%, or within a tolerance of +/−5% (such that, for example, a spacing between opposite inner surfaces is equal, within a tolerance of +/−10% or within a tolerance of +/−5%, when leaving the ridges unconsidered), and wherein a ratio between a maximum distance of a first pair of opposite inner surfaces (e.g. 5.2 mm) and radial extensions (e.g. extensions in a direction perpendicular to a respective inner surface and toward the axis of the ridged waveguide structure) (e.g. 1 mm) of ridges arranged at the inner surfaces of the first pair of inner surfaces is 5.2 mm, with a tolerance of +/−10, or with a tolerance of +/−5%, and wherein a ratio between a maximum distance of a second pair of opposite inner surfaces (e.g. 5.2 mm) and radial extensions (e.g. extensions in a direction perpendicular to a respective inner surface and toward the axis of the ridged waveguide structure) (e.g. 1 mm) of ridges arranged at the inner surfaces of the second pair of inner surfaces is 5.2 mm, with a tolerance of +/−10, or with a tolerance pf +/−5%, and wherein a ratio between a width of a respective ridge (e.g. 1.2 mm) (e.g. measured in parallel with a respective inner surface on which the respective ridge is arranged) and a width of a respective inner surface on which the respective ridge is arranged (e.g. 5.2 mm), is 0.23 mm, with a tolerance of +/−10% or +/−5%.

Such dimensions provide a wide bandwidth (e.g. a wide mono-mode bandwidth) (e.g., above 24 GHz) while providing good transmission characteristics (e.g. in terms of scattering parameters S_{1,2}, S_{2,1} and S_{1,1}, S_{2,2}) within the bandwidth.

According to an embodiment, the antenna structure is a dual-polarized antenna structure, and wherein the antenna device is configured (e.g. comprises an appropriate feeding structure) such that a first propagation mode of the ridged waveguide structure couples predominantly (e.g. to more than 80%, or to more than 90%) with a first polarization of the dual-polarized antenna structure, and such that a second propagation mode of the ridged waveguide structure couples predominantly (e.g. to more than 80%, or to more than 90%) with a second polarization of the dual-polarized antenna structure, which is different form the first polarization.

Thus, signals for the first and second polarizations can be coupled into the first waveguide flange with four ridges (e.g., a quad-ridged waveguide), which can be guided (at least partly) independently in the ridged waveguide structure with the four ridges. Accordingly, a single (blind mating) waveguide connection is sufficient to separately transmit signals associated with two different (e.g. orthogonal) polarizations. The antenna device can easily be coupled to an automated test equipment and polarization-separated signals can be exchanged unidirectionally or bidirectionally between components of the automated test equipment and the antenna.

An embodiment according to the invention is directed to an automated test equipment, comprising the antenna device as described herein, and a test fixture (e.g. a test head structure or a load board structure) with a second blind mating waveguide flange configured to be coupled to the first waveguide flange of the antenna device, wherein the second waveguide flange comprises a ridged waveguide structure that mates with the ridged waveguide structure of the first waveguide flange (wherein, for example, a cross-section of the ridged waveguide structure of the second waveguide flange may, for example, be identical, except for fabrication tolerances, with a cross-section of the ridged waveguide structure of the first waveguide flange).

Since the first and second waveguide flanges can mate and are coupleable, the test fixture and the antenna device can be coupled such that electromagnetic waves can be transmitted therebetween. Since the first waveguide flange is a blind mating flange and has a ridged waveguide structure, electromagnetic waves can be transmitted over a wide bandwidth that is enabled by the ridged waveguide structure and mating (an alignment) with the second waveguide flange can be performed in a blind manner.

According to an embodiment, the second waveguide flange is depressible (e.g., by applying a mating force onto the second waveguide flange via the mating first waveguide flange) against a bias (e.g., a spring structure and/or a resilience of a waveguide coupled to the second waveguide flange) in a direction that extends essentially perpendicular to a face of the second waveguide flange. As a result, a mating force (contact force) may be provided, which helps to ensure a reliable connection. Moreover, in some cases, the antenna device can be arranged at (slightly) different distances relative to the text fixture (e.g., in order to increase compatibility with differently sized devices under test and/or realizing an early contact between the first and second waveguide flanges during a coupling procedure) while still enabling a (reliable) physical contact between the first and second waveguide flanges.

According to an embodiment, the second waveguide flange is mounted to be floating (e.g. in a direction parallel to the a face surface of the second waveguide flange) (e.g. mounted on a floating assembly). Since the first waveguide flange is configured to be blind mating, it may entail (at least a slight) movement of at least one of the first and second waveguide flange for alignment (e.g. for self-alignment guided, for example, by one or more conical alignment pins, or the like). With the second waveguide flange being mounted to be floating, the second waveguide flange is able to move during a coupling with the first waveguide flange and may therefore improve the coupling process (for example, by compensating some positioning inaccuracies of the first waveguide flange). The second waveguide flange can provide a robust blind mating interconnect, e.g., if proper care is taken on a surface plating.

According to an embodiment, the test fixture comprises a device under test socket configured to electrically couple to the device under test. The device under test socket may therefore realize an interface for sending and/or receiving electrical signals (e.g. wired signals) to/from the device under test. For example, the device under test socket may allow sending control signals (e.g. causing the device under test to emit electromagnetic radiation) and/or receiving (e.g. wired) measurement signals of the device under test, and or power signals to power the device under test.

According to an embodiment, the second waveguide flange comprises a removable face structure (e.g. a structure comprising a straight waveguide portion) that comprises a face of the second waveguide flange. The removable face structure can be exchanged or removed for repairing after being worn down by repeated coupling procedures. The wear is therefore (substantially) limited to a smaller structure (for example, the removable face structure) that can be replaced and/or repaired. This avoids changing the second waveguide flange (or a waveguide-to-coaxial adapter that it is a part of), which commonly is a more expensive component. Furthermore, there is no need to use any special plating on the second waveguide flange.

According to an embodiment, the removeable face structure (of the second waveguide flange) is at least partially plated with a plating that comprises at least one of nickel and gold (wherein, for example, the plating may comprise a gold layer with a thickness in a range of 1.5 μm to 2.5 μm and a nickel layer with a thickness in a range of 0.5 μm and 1.2 μm).

It has been recognized that a plating comprising gold is stable for many coupling processes (e.g., over a million coupling processes) and that nickel improves wear resistance (e.g., as barrier metal).

According to an embodiment, the second waveguide flange has a substantially rectangular cross section with two wide inner surfaces and two narrow inner surfaces that are narrower than the wide inner surfaces, wherein a first and second ridge of the ridged waveguide structure extend towards each other from the wide inner surfaces (such that a double-ridged waveguide is formed) (wherein details regarding the geometry may, for example, be equal to geometrical details of the first waveguide flange).

The first and second waveguide flanges therefore both have a ridged waveguide structure with two ridges (which may, for example, be located adjacently, e.g. to from a homogenous cross-section, when the first waveguide flange and the second waveguide flange are mated). As a result, the first and second waveguide flanges both benefit from an increased bandwidth and a reduced signal loss at a transition between the first and second waveguide flange. Moreover, a discontinuity at the transition between the flanges can be avoided by using same or similar cross-sections.

According to an embodiment, the second waveguide flange has a substantially rectangular (e.g. square) cross section with four inner surfaces (e.g. of equal width), wherein the ridged waveguide structure of the second waveguide flange comprises four ridges, each of the four ridges extending from a respective one of the four inner surfaces towards a central axis of the first waveguide flange (such that a quad-ridged waveguide structure is formed) (wherein details regarding the geometry may, for example, be equal to geometrical details of the first waveguide flange).

As a result, the second waveguide flange may be able to guide wideband signals of two different polarization orientations. For example, the first waveguide flange may also have four ridges, which allow guiding wideband signals of two different polarization orientations, which may be transmitted into the second waveguide flange, or vice versa.

According to an embodiment, the automated test equipment comprises a waveguide-to-coaxial adapter which is coupled to the second blind mating waveguide flange, to establish a connection between ATE instrumentation (e.g. one or more signal generators and/or one or more signal evaluators) and the second blind-mating waveguide flange.

An embodiment according to the invention is directed at a method for testing a device under test, wherein the method comprises establishing a coupling between a device under test and an automated test equipment using an antenna device, wherein the antenna device comprises an antenna structure, and a first blind mating waveguide flange coupled to the antenna structure, wherein the first waveguide flange comprises a ridged waveguide structure with at least two ridges, coupling the first waveguide flange to a second blind mating waveguide flange of an automated test equipment (wherein the second blind-mating waveguide flange may, for example, be attached, e.g. in a floating manner, to a test fixture of the automated test equipment).

The coupling between the first and second waveguide flanges can be realized in form of blind mating. Therefore the coupling uses some alignment structure and provides sufficient accuracy in automated coupling. Since a wireless coupling is established between the device under test and the antenna device, a communicative connection can be established between the device under test and the automated test equipment via the antenna device.

According to an embodiment, the method comprises electrically coupling (e.g. in a wired manner) the device under test to a test socket of the automated test equipment (wherein the test socket may, for example, be arranged on a test fixture or may be part of a test fixture).

As a result, the automated test equipment can send or receive electrical signals to/from the device under test via the test socket. For example, the automated test equipment may send control signals (e.g., to cause emission of electromagnetic radiation) to the device under test and/or receive measurement signals from the device under test.

According to an embodiment, the method may comprise transmitting a signal between the device under test and the automated test equipment at least via the antenna structure, the first waveguide flange, and the second waveguide flange. Signal transmission may be occur from the device under test to the automated test equipment and/or vice versa.

The signal transmission allows evaluating of a signal received from or transmitted to the device under test (e.g., by the automated test equipment). The signal transmission benefits from the wide frequency bandwidth of (at least) the ridged first waveguide flange, since a transmission frequency is selectable within the wide bandwidth of the ridged first waveguide flange.

According to an embodiment, the second waveguide flange is depressible against a bias (e.g. spring loaded) in a direction that extends essentially perpendicular to a face of the second waveguide flange, wherein coupling the first waveguide flange to the second waveguide flange comprises pressing a face of the first waveguide flange onto a face of the second waveguide flange against the bias of the second waveguide flange, and attaching the antenna device to the test fixture.

Due to the depressability and bias of the second waveguide flange, the step of pressing the face of the first waveguide flange onto the face of the second waveguide flange can be performed with a larger variety of devices (e.g., with varying thickness). A good connection can be established, since the (mechanical) bias of the second waveguide flange may help to have a sufficient mating force.

### BRIEF DESCRIPTION OF THE DRAWINGS

The drawings are not necessarily to scale, emphasis instead generally being placed upon illustrating the principles of the invention. In the following description, various embodiments of the invention are described with reference to the following drawings, in which:

FIG. 1 shows a schematic view of an embodiment of an antenna device for establishing a wireless coupling to a device under test;

FIG. 2A shows an example of a cross-section of a first waveguide flange with a ridged waveguide structure having two ridges;

FIG. 2B shows a graphic representation of a result of a simulation of insertion loss and return loss of the waveguide flange of FIG. 2A;

FIG. 3A shows an example of a squared cross-section of a first waveguide flange with a ridged waveguide structure having four ridges;

FIG. 3B shows a result of a simulation of a vertical polarization in the first waveguide flange shown in FIG. 3A;

FIG. 3C shows a graphic representation of a result of a simulation of scattering parameters for the first waveguide flange shown in FIGS. 3A and B;

FIG. 4 shows a perspective view of an embodiment of an antenna device with an antenna structure and a first blind mating waveguide flange having a ridged waveguide structure;

FIG. 5A shows a side view of a first example of a protrusion with a conical surface and a round tip;

FIG. 5B shows a side view of a second example of a protrusion with a shaft and a truncated cone tip;

FIG. 5C shows a side view of a third example of a protrusion with two conical surfaces having different diameters;

FIG. 5D shows a side view of a forth example of a protrusion with a circumferential projection around a shaft;

FIG. 6 shows a perspective view of an embodiment of a first waveguide flange, wherein a first face of the first waveguide flange comprises a choke structure;

FIG. 7A shows a schematic side view of an embodiment of an antenna device, wherein the first waveguide flange comprises a removable face structure that comprises a face of the first waveguide flange;

FIG. 7B shows a schematic side view of the antenna device of FIG. 7A, wherein the face structure is removed from the housing;

FIG. 7C shows a perspective view of the face structure;

FIG. 8A shows show a cross section captured by scanning electron microscopy of a plating of the face structure before being used in repeated mating cycles;

FIG. 8B shows a cross section captured by SEM of the plating of the face structure after being used in over one million mating cycles;

FIG. 9 shows a schematic view of a cross section of an automated test equipment;

FIG. 10A shows a perspective view of a waveguide-to-coaxial adapter of the test fixture;

FIG. 10B shows a different perspective view of the waveguide-to-coaxial adapter of FIG. 10A;

FIG. 10C shows a further different perspective view of the waveguide-to-coaxial adapter of FIGS. 10A, B;

FIG. 11A shows a perspective view of a waveguide-to-coaxial adapter comprising a first housing portion and a second housing portion;

FIG. 11B shows a perspective view of the first housing portion;

FIG. 12A shows a perspective view of the second housing portion;

FIG. 12B shows a diagram of a simulated return loss of a waveguide-to-coaxial adapter with under 50 μm manufacturing deviations;

FIG. 13 shows a perspective view of an example of an antenna device and a waveguide-to-coaxial adapter;

FIG. 14 shows a perspective view of the antenna device and the waveguide-to-coaxial adapter of FIG. 13;

FIG. 15 shows a perspective view of the antenna device and the waveguide-to-coaxial adapter of FIGS. 13, 14;

FIG. 16 shows a schematic view of an automated test equipment with the antenna device, the waveguide-to-coaxial adapter, and an ATE instrumentation; and

FIG. 17 shows a schematic view of a flow diagram of a method for testing the device under test.

### DETAILED DESCRIPTION OF THE INVENTION

Equal or equivalent elements or elements with equal or equivalent functionality are denoted in the following description by equal or equivalent reference numerals even if occurring in different figures.

In the following description, a plurality of details is set forth to provide a more throughout explanation of embodiments of the present invention. However, it will be apparent to those skilled in the art that embodiments of the present invention may be practiced without these specific details. In other instances, well-known structures and devices are shown in block diagram form rather than in detail in order to avoid obscuring embodiments of the present invention. In addition, features of the different embodiments described herein after may be combined with each other, unless specifically noted otherwise.

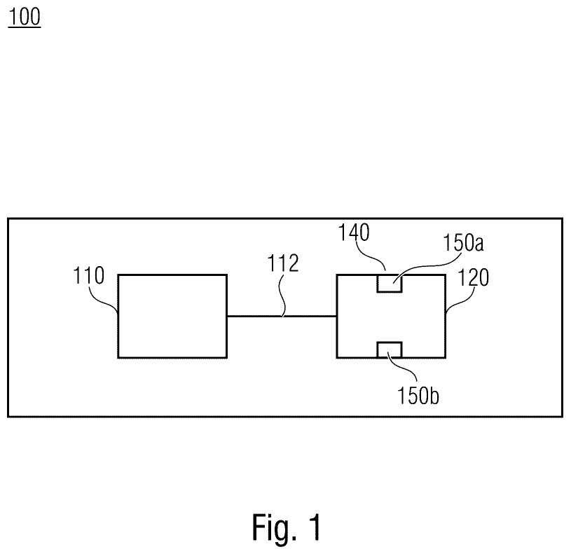

FIG. 1 shows a schematic view of an embodiment of an antenna device 100 for establishing a wireless coupling to a device under test (not shown). The antenna device 100 comprises an antenna structure 110 and a first blind mating waveguide flange 120 coupled to the antenna structure 110, wherein the first waveguide flange 120 comprises a ridged waveguide structure 140 with at least two ridges 150a, b.

The antenna structure 110 may comprise a radiating aperture. For example, the antenna structure 110 may comprise an end face of a waveguide (e.g., with an oblong rectangular or squared shape, optionally also comprising a ridged waveguide structure). In this case, for example, the waveguide of the antenna structure 110 may have an at least essentially identical cross section as the first waveguide flange 120. The antenna structure 110 may, for example, be formed by or comprise an opening in a metal housing. In some embodiments, the antenna structure 110 may, for example, be formed by or comprise at least one of a monopole antenna, a dipole antenna, a horn antenna, and a parabolic antenna. The antenna structure 110 may, for example, comprise (or be a part of) an antenna array.

The first blind mating waveguide flange 120 is coupled to the antenna structure 110, i.e. an electromagnetic wave received by the antenna structure 110 is transmitted to the first blind mating waveguide flange 120 (and vice versa). The first waveguide flange 120 may, for example, be coupled to the antenna structure 110 via a coupling element 112. The coupling element 112 may, for example, comprise at least one of a waveguide, a cable, a printed circuit board structure, an air interface, an amplifier, and a waveguide splitter/combiner structure (e.g., a T-junction). The coupling element 112 may, for example, comprise a connecting waveguide (optionally with a waveguide splitter/combiner structure) with at least two end faces, wherein one end face forms or comprises the antenna structure 110 and the other end face forms of comprises the first waveguide flange 120. The coupling element 112 (e.g., the connecting waveguide) may, for example, extend (e.g., be routed) in a U-shape (e.g. such that a main lobe direction of the antenna structure is directed in a same direction like the first waveguide flange 120).

The first waveguide flange 120 may be arranged at an end of a waveguide, e.g., of a waveguide with an at least essentially identical cross section as the first waveguide flange 120 (e.g., including the ridged waveguide structure 140 in the cross-section). The first waveguide flange 120 (and optionally a waveguide connected thereto) may have a (substantially) rectangular (e.g., oblong rectangular or squared) cross-section.

For example, the first waveguide flange 120 may have a cross-section with a width in in a range of 5.3 mm to 5.7 mm or in a range between 5.4 mm and 5.6 mm, or in a range between 5.44 mm and 5.54 mm, e.g., at least essentially 5.49 mm. The first waveguide flange 120 may have a cross-section with a height in a range of 2.4 mm and 2.7 mm or in a range between 2.5 mm and 2.6 mm, e.g., at least essentially 2.55 mm. Alternatively, the first waveguide flange 120 may have an at least essentially square cross-section with a width in a range of 5 mm to 6 mm, e.g., 5.1 mm to 5.3 mm, e.g., at least essentially 5.2 mm.

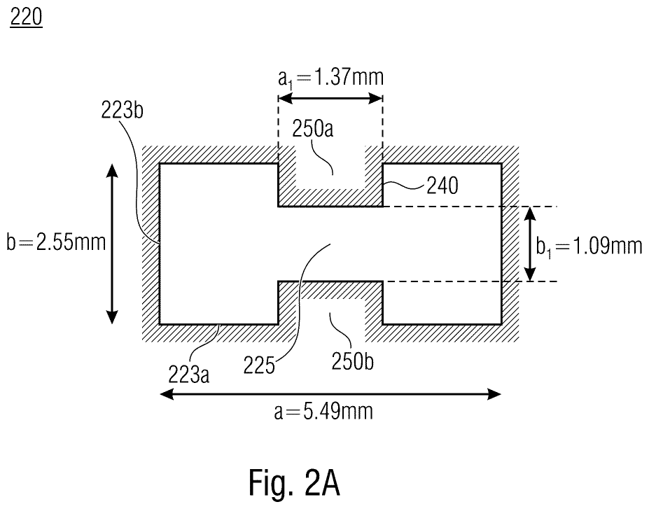

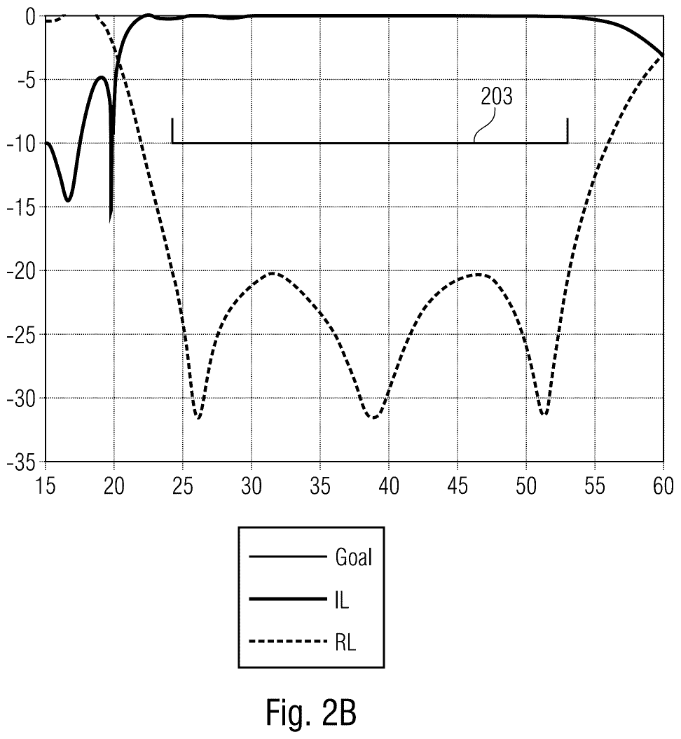

FIG. 2A shows an example of a cross-section of a first waveguide flange 220 with a ridged waveguide structure 240 having two ridges 250a, b. The first waveguide flange 220 has width a (e.g., (total) width of a wide inner surface 223a) of, for example, 5.49 mm and a height b (e.g., (total) width of a short inner surface 223b) of, for example, 2.55 mm. The two ridges 250, b extend from (or are arranged at) the wide inner surfaces 223a of the first waveguide flange 220. The ridges 250a, b are arranged centrally along a width of the wide inner surfaces 223a. A gap 225 between the ridges 250a, b has a width b₁ of, for example, 1.09 mm. The two ridges 250a, b have at least essentially identical cross sections. Alternatively, the ridges 250a, b may have different cross sections. The ridges 250a, b have a height (e.g. measured in a radial direction from a central axis of the waveguide) of, for example, 0.73 mm (i.e. (b−b₁)/2=(2.55 mm-1.09 mm)/2=0.73 mm). The ridges 250a, b have a width a₁ (e.g. in a direction parallel to the wide inner surface 223a) of, for example, 1.37 mm. It is noted that the first waveguide flange 220 may be dimensioned differently. For example, at least one of the dimensions described herein may be different.

Alternatively or additionally, the scale of the entire cross-section may be different (e.g., all dimensions may be scaled up or down by a common factor such as, for example, by 2).

According to an embodiment, a ratio between a width of the wide inner surface 223a and a width of the narrow inner surface is 2.15, with a tolerance of +/−10 percent (or within a tolerance of +/−5%). In the example shown in FIG. 2A, the ratio of widths a and b is approximately a/b=5.49 mm/2.55 mm≈2.15. A ratio between a width of the wide inner surface 223a and a width of a gap 225 between the first ridge and the second ridge may be 5.04, with a tolerance of +/−10 percent (or within a tolerance of +/−5%). In the example shown in FIG. 2A, the ratio of widths a and b₁ is approximately a/b₁=5.49 mm/1.09 mm; 5.04. A ratio between a width of the wide inner surface 223a and a width of the first ridge and of the second ridge may be 4.01, with a tolerance of +/−10 percent (or within a tolerance of +/−5%). In the example shown in FIG. 2A, the ratio of a and a₁ is approximately a/a₁=5.49 mm/1.37 mm≈4.01.

FIG. 2B shows a graphic representation of a simulation of insertion loss (IL, dark solid line) and return loss (RL, dashed line) of a waveguide flange 220 with the dimensions as described herein with reference to FIG. 2A. The horizontal axis indicates a frequency in GHz (i.e., from 15 to 60 GHz) and the vertical axis indicates the IL and RL in dB (wherein the insertion loss should advantageously be represented by a positive number). A grey solid line 203 (see horizontal line at −10 dB) indicates a goal bandwidth of 24 to 53 GHz. As can be seen in the plot of the simulation, the insertion loss is approximately zero and the return loss is approximately between 20 to 32 dB within the goal bandwidth.

The first waveguide flange 120 (and optionally the waveguide connected thereto) may, for example, have a squared cross section, for example with an inner surface having a width of 5.1 mm to 5.3 mm, e.g., 5.15 mm to 5.25 mm, e.g., at least essentially 5.2 mm. The ridged waveguide structure may, for example, have four ridges each having, for example, a height (in a direction perpendicular to the inner surface that the respective ridge extends from) of 0.9 mm to 1.1 mm, e.g., 0.95 mm to 1.05 mm, e.g. at least essentially 1 mm. The ridges may, for example, have a width (in a direction parallel to the inner surface that the respective ridge extends from) of 1.1 mm to 1.3 mm, e.g., 1.15 mm to 1.25 mm, e.g., at least essentially 1.1 mm.

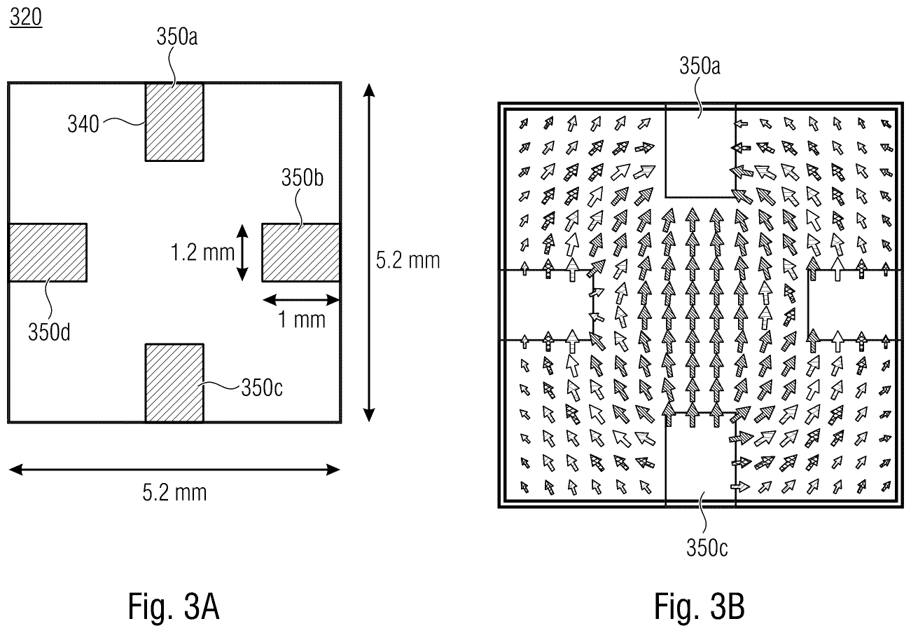

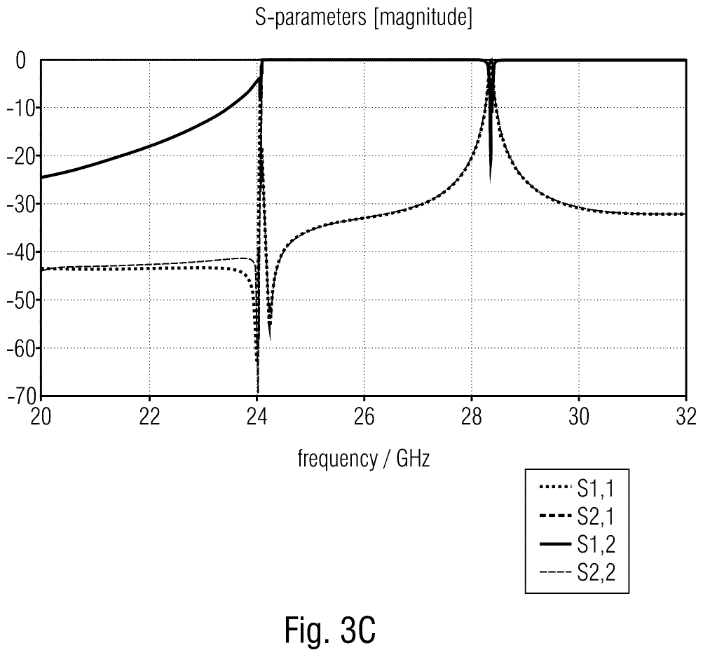

FIG. 3A shows an example of a cross-sectional view of a first waveguide flange 320 with a ridged waveguide structure 340 having four ridges 350a-d (also called a quad-ridged waveguide flange). The first waveguide flange 320 has a square cross-section, wherein each of the four inner surfaces has a width of 5.2 mm. From a centre of each inner surface extends a respective one of the four ridges 350a-d, wherein a respective one of the ridges 350a,b extends towards a respective opposite ridge 350c,d (e.g., in FIG. 3A, the left ridge 350d extends towards the right ridge 350b). The four ridges 350a-d depicted in FIG. 3A have, for example, identical cross-sections (when disregarding orientation, as ridges 350b, d are shown to be rotated by 90° relative to ridges 350a, c). Alternatively, at least one of the ridges 350a-d may have a different cross section (e.g., a different width or length). The ridges 350a-d have a height (in a (radial) direction perpendicular to the inner surface that the respective ridge 350a-d extends from) of, for example, 1 mm. Therefore, a gap of, for example, 3.2 mm (e.g., 5.2 mm-(2*1 mm)=3.2 mm) is formed between a pair of opposite ridges 350a,c or 350b,d. The ridges 350a-d have a width (in a direction parallel to the inner surface that the respective ridge 350a-d extends from) of, for example, 1.2 mm.

The ridged waveguide structure 340 having four ridges 350a-d essentially forms a combination of two double ridge interconnects into a single quad-ridge interconnect.

FIG. 3B shows a result of a simulation of a vertical polarization (or, more precisely, of a vertically polarized mode) in the first waveguide flange 320 shown in FIG. 3A. The four ridges 350a-d allow excitation of the vertical polarization.

FIG. 3C shows a graphic representation of results of a simulation of scattering parameters (S-parameters) for the first waveguide flange 320 shown in FIGS. 3A and B. The horizontal axis indicates a frequency in GHz (i.e., from 20 to 32 GHz) and the vertical axis indicates a magnitude of scattering parameters S_{1,1}, S_{2,1}, S_{1,2}, and S_{2,2} in dB. The magnitude of the parameters S_{1,1} and S_{2,2} coincide for the most part and the magnitude of the parameters S_{2,1} and S_{1,2} coincide entirely. The magnitude of the parameters S_{1,1} and S_{2,2} is lower than the magnitude of the parameters S_{2,1} and S_{1,2} between approximately 24.2 GHZ and 28.2 GHz as well as between 28.7 GHz and 32 GHz, indicating low reflectance and high transmittance. Only between approximately 24.2 GHz and 28.2 GHz the magnitudes of the S-parameters show a reversed behaviour. An advantage of the quad-ridged waveguide flange is the ability to carry two polarizations. However, the implementation shown in FIG. 3A may perform at a smaller bandwidth compared to an implementation with a double-ridged waveguide. However, the results of the simulation shown in FIG. 3C are based on a non-optimized design. It should be noted that optimization of parameters of the first waveguide flange (e.g., dimensions) may result in a significantly broader bandwidth.

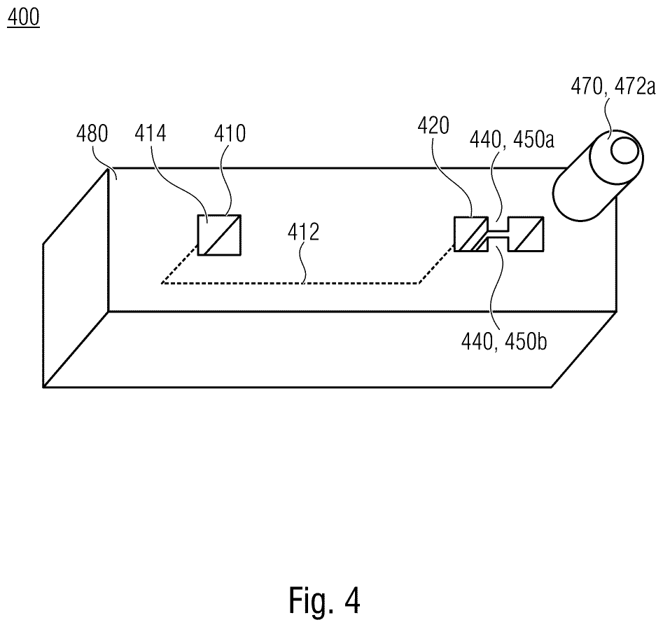

FIG. 4 shows a schematic perspective view of an embodiment of an antenna device 400 with an antenna structure 410 and a first blind mating waveguide flange 420 having a ridged waveguide structure 440. In the example shown in FIG. 4, the first waveguide flange 420 has an oblong rectangular overall cross-section and the ridged waveguide structure 440 (which is part of the first waveguide flange and which modifies the overall cross-section of the first waveguide flange) has two ridges 450a, b. The first waveguide flange 420 has two wide (i.e. comparatively wider) inner surfaces and two short (i.e. comparatively shorter) inner surfaces. The respective ridges 450a, b extend towards each other from a middle of each respective wide inner surface.

The ridges 450a, b have an oblong rectangular cross section, wherein a wide side of each of the ridges 450a, b extends parallel to the wide side of the first waveguide flange 420. As a result, the wide sides of the ridges 450a, b, face each other. Alternatively, the short sides of the ridges 450a, b, may face each other. Further alternatively, the ridges 450a, b may have a square cross-section. The first waveguide flange 440 may, for example, have the same (or similar) dimensions as the ones shown in FIG. 2A.

The double-ridged first waveguide flange 420 has an increased bandwidth (or a wide bandwidth) (e.g., 24 to 53 GHz) and allows testing devices within the increased bandwidth using only a single (wideband) antenna device (e.g., antenna device 400) instead of a plurality of conventional antenna devices that are (conventionally) used to cover the increased bandwidth in combination.

For example, the antenna structure 410 depicted in FIG. 4 comprises (or is formed by) an aperture 414 within a (e.g., metal) housing 480. The housing 480 may comprise a plurality of (e.g., two, three, or more) layers. For example, at least one of the antenna structure 410, the aperture 414, the coupling element 412, the first waveguide flange 420, and the ridged waveguide structure 440 may be formed at least partially by recesses in two adjacent layers of the housing 480.

The first waveguide flange 420 comprises a first blind mating interface 470, which comprises, for example, an exemplary single protrusion 472a. Generally speaking, the first blind mating interface 470 may, for example, comprise one or more protrusions and/or one or more recesses, which allow for a self-mating alignment between the first waveguide flange 420 and a mating (e.g. second) waveguide flange. The first waveguide flange 420 may, for example, comprise at least one first protrusion and at least one recess configured receive a second protrusion of the same shape (or at least essentially the same shape) as the first protrusion. As a result, during a blind mating procedure insertion of the first and second protrusion can occur simultaneously. Alternatively, the recess may be configured to receive a second protrusion that is longer or shorter than the first protrusion. As a result, a blind mating procedure can be achieved with two temporally subsequent alignment phases, e.g., enabling different alignment steps. However, it should be noted that different alignment structures could also be used to allow for the blind mating of the first waveguide flange with another waveguide flange, like, for example, alignment structures coaxially surrounding the aperture 414. However, any type of self-aligning features may be used in embodiments according to the invention.

In the case that a protrusion is used as a self-mating alignment means, the protrusion may, for example, be attached to (e.g., screwed into, screwed through, welded to or integrally formed with) a face of the first waveguide flange 420 and/or any other part of the antenna device 400 (e.g., the housing 480). The protrusion may be attachable (and optionally removable) from the face of the first waveguide flange 420.

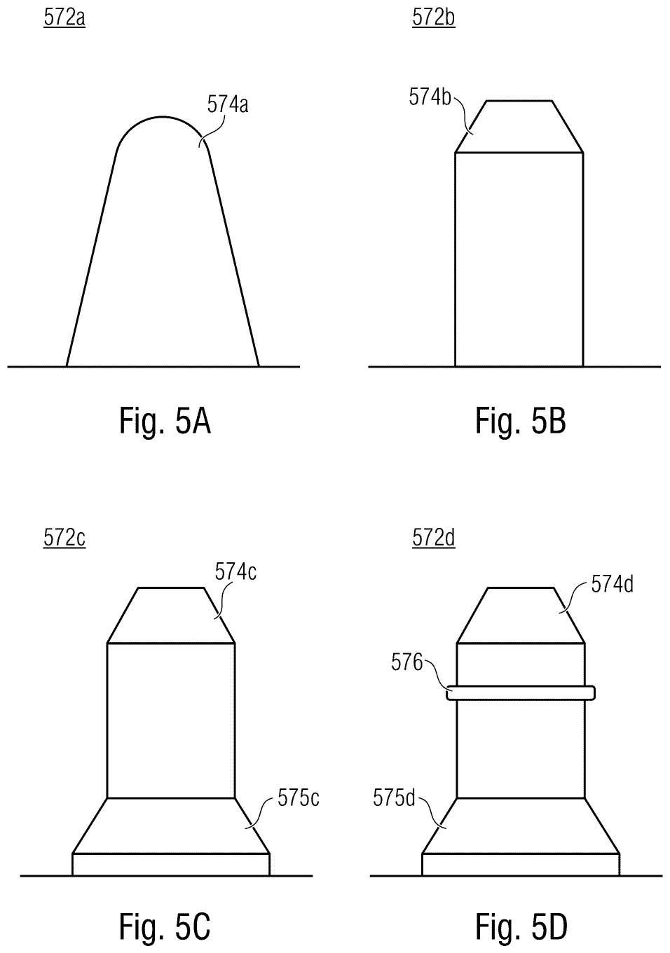

FIGS. 5A to 5D show different examples of protrusions 572a-d, which may, for example, serve as alignment structures for the blind mating, and which may, for example, take the role of the protrusion 472a. It is to be understood that alternatively or additionally to one or more protrusions 572a-d, the first blind mating interface 470 may comprise one or more similarly (e.g. fittingly) shaped (e.g., inverted) recesses configured to receive a protrusion such as the protrusions described herein.

FIG. 5A shows a side view of a first example of a protrusion 572a with a conical surface 574a and a round tip. The conical surface 571a of the protrusion 572a causes the protrusion to self-align when received by a corresponding recess.

FIG. 5B shows a side view of a second example of a protrusion 572b with a shaft and a truncated cone tip. The truncated cone tip provides a conical surface 574b for self-alignment. The shaft provides a lateral abutment surface that limits lateral movement.

FIG. 5C shows a side view of a third example of a protrusion 572c with two conical surfaces 574c, 575c having different diameters (e.g., different diameters at the at a base of the each conical surface 574c, 575c). The two conical surfaces 574c, 575c form two stages for rough alignment (e.g., with smaller diameter, see upper conical surface 574c in FIG. 5C) and for fine alignment (e.g., with larger diameter, see lower conical surface 575c in FIG. 5C).

FIG. 5D shows a side view of a forth example of a protrusion 572d with a circumferential projection 576 (e.g., in the shape of a ring) around the shaft. The projection 576 may be formed integrally with the rest of the protrusion 572d.

Alternatively, the projection 576 may be a separate portion, e.g., comprising metal or a polymer (such as rubber). The projection 576 may abut against a surface of the shaft or a conical surface 574d, 575d or be arranged in a groove of the shaft or a conical surface 574d, 575d. The projection 576 can, for example, frictionally engage with a receiving recess and/or absorb excessive forces during the mating process. The protrusion 572d of FIG. 5D may correspond to the protrusion 572c of FIG. 5C, except for the fact that the projection 576 is added to the protrusion 572d of FIG. 5D. However, the projection 576 may be used in combination with any other protrusion described herein, e.g. in combination with the protrusions 572a, 572b.

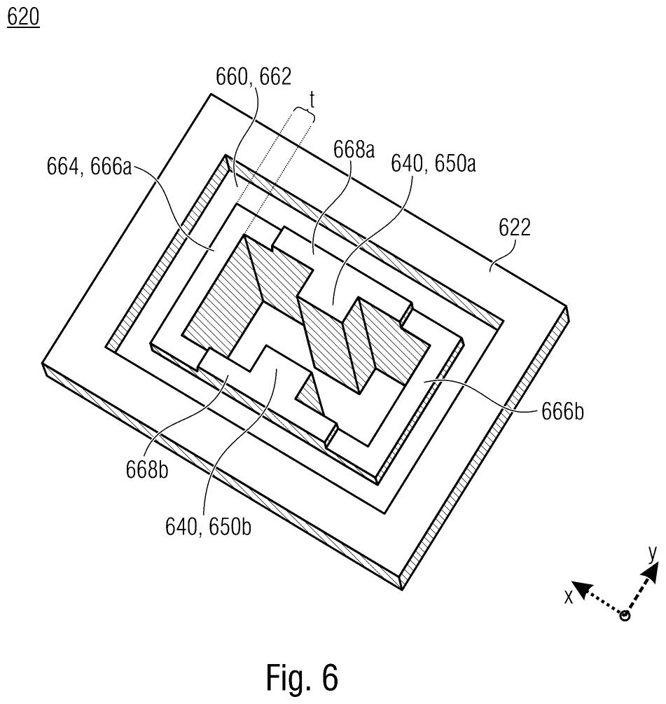

FIG. 6 shows a perspective view of an embodiment of a first waveguide flange 620, wherein a first face 622 of the first waveguide flange 620 comprises a choke structure 660. The first waveguide flange 620 shown in FIG. 6 comprises, in a central area, a ridged waveguide structure 640 with two ridges 650a, 650b. The choke structure 660 is arranged to surround the ridged waveguide structure 640. However, in some embodiments, and possibly with some modifications, the choke structure 660 can be used with any other number of ridges (e.g., four ridges).

The first face 622 is a (optionally flat) surface of the first waveguide flange 620 facing away from a waveguide feeding the first waveguide flange 620. The first face 622 is oriented perpendicular to an extension direction of the feeding waveguide. The choke structure 660 comprises a recess 662 formed in the first face 622 and extends at least partly or entirely (e.g. as seen in FIG. 6) around an inner wave-guiding structure of the first waveguide flange 620 (e.g., an aperture of the feeding waveguide).

The recess 662 shown in FIG. 6 extends, for example, along a rectangular path, e.g., in such a way that a boundary 664 formed between the recess 662 and the inner surfaces of the first waveguide flange 620 has at least essentially the same thickness t at a short and a long side of the boundary 664. Alternatively, the boundary 664 may have a different wall thickness at at least one of the its fours sides. Further alternatively, the recess 662 may have any other path such as a circle, oval, or a (e.g., regular) polygon (e.g., with rounded corners). The boundary 664 may have a wall thickness of at least essentially a quarter of a wavelength of an operational frequency of the waveguide flange 620. The operational frequency may, for example, be a centre frequency (e.g., 38.5 GHz), a lower cutoff frequency (e.g., 24 GHz), an “upper cutoff” frequency (e.g. a frequency at which the waveguide starts to carry more than one non-evanescent mode) (e.g., 53 GHz), or any frequency therebetween.

The boundary 664 may comprise coupling recesses 666a, 666b in regions of two (further) sides of the boundary 664 (e.g. in regions of opposite shorter sides or opposite shorter boundaries) of the substantially rectangular cross-section of the inner wave-guiding structure, to allow for a coupling between the inner wave-guiding structure and the recess 662 surrounding the inner wave-guiding structure

The coupling recesses 666a,666b are recessed (in a direction perpendicular to the first face 622) compared to the first face 622 of the first waveguide flange 620. The boundary 664 may have a non-recessed boundary portion 668a (and typically also a non-recessed boundary portion 668b), e.g., that has a face surface that is flush with the first face 622 of the first waveguide flange 620. The ridges 650a, 650b may terminate at (or may transition into, or may be part of) the non-recessed boundary portions 668a,668b. The non-recessed boundary portions 668a,668b may have a T-shape. Alternatively, the non-recessed boundary portions may, for example, have an L-shape, I-Shape, or E-shape.

The first waveguide flange 620 comprising the ridged waveguide structure 640 may be dimensioned such as to realize a resonance stub (e.g. using the recess 662 and the coupling recesses 666a,666b). For example, recess 662 may have a depth of at least essentially a quarter of a wavelength of an operational frequency of the waveguide flange 620. The operational frequency may be a centre frequency (e.g., 38.5 GHz), a lower cutoff frequency (e.g., 24 GHz), an “upper cutoff” frequency (e.g. a frequency at which the waveguide starts to carry more than one non-evanescent mode) (e.g., 53 GHz), or any frequency therebetween.

It should be noted that the first waveguide flange 620 may optionally be used in any of the antenna devices disclosed herein.

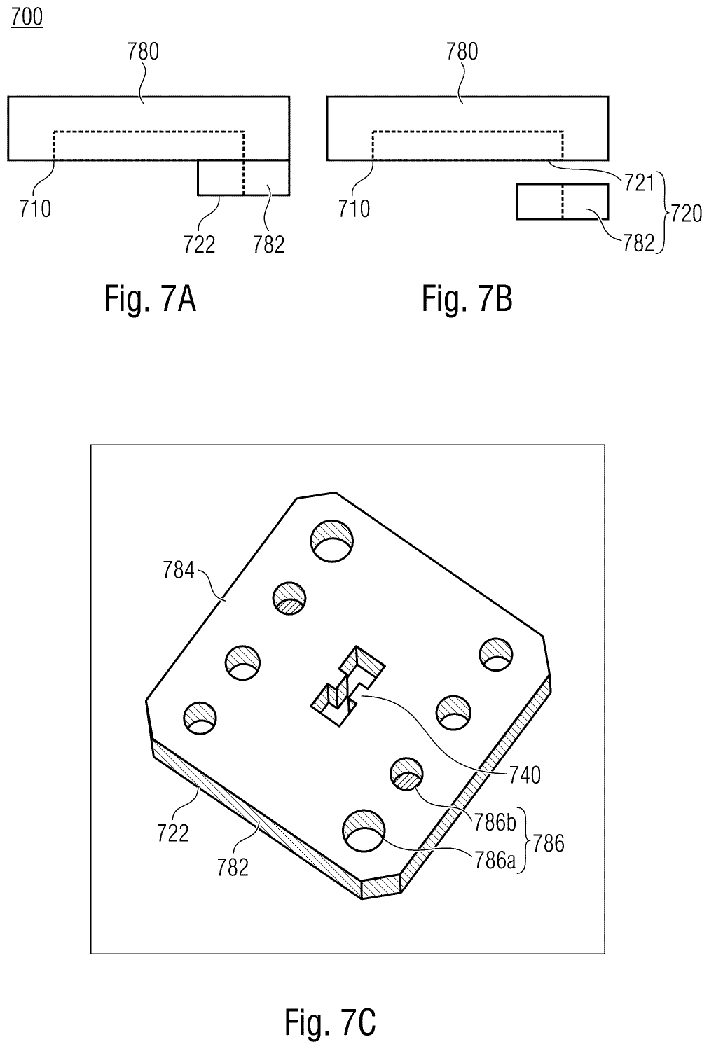

FIG. 7A shows a schematic side view of an embodiment of an antenna device 700 according to an embodiment of the present invention, wherein the first waveguide flange 720 comprises a removable face structure 782 that comprises the face 722 of the first waveguide flange 720. In FIG. 7A, the face structure 782 is attached to the housing 780. A signal path from the antenna structure 710 to an aperture of the face 722 is (schematically) indicated with a dashed line.

FIG. 7B shows a schematic side view of the antenna device 700 of FIG. 7A, wherein the face structure 782 is removed from the housing 780. The housing 780 includes a waveguide, for example, with a first (e.g. tapered) aperture forming the antenna structure 710 and a second aperture that can (in principle) act as a first waveguide flange. However, when the face structure 782 is attached to the housing 780, the face structure 782 can act at least as a part of the first waveguide flange.

In order to designate elements of an antenna device 700 having a removable face structure 782, the second aperture of the housing 780 is termed first waveguide base flange 721 and the first waveguide flange 720 comprises the first waveguide base flange 721 and the removable face structure 782. However, it is noted that in absence of the removable face structure 782, the first waveguide base flange 721 may be used as a first waveguide flange.

FIG. 7C shows a perspective view of the face structure 782. The face structure 782 has a connecting surface 784 that faces the antenna device 700 when the face structure 782 is attached to the housing 780. The connecting surface 784 is opposite the face 722 of the face structure 782 (and opposite to the “overall” face of the first blind mating waveguide flange, when the face structure 782 is attached to the housing 780) (wherein the face 722 of the face structure forms the “overall” face of the blind mating waveguide structure when the face structure is attached to the housing 780).

The face structure 782 comprises a plurality of holes 786. The holes 786 may be through holes 786a or blind holes 786b. The holes can be configured to receive protrusions (e.g, protrusions 572a,b,c,d) and/or to receive an attachment element (e.g., a screw), e.g., for attaching the face structure 782 to the housing 780 or attaching the face structure 782 to another waveguide flange.

The face structure 782 may comprise at least one of the ridged waveguide structure 740 and a choke structure (which is not visible in FIG. 7C as the choke structure would be arranged at the face 722).

The face structure 782 may be at least partially plated (e.g., at least partially or entirely plated on the face 722 and/or on other surfaces of the face structure 782) with a plating. The entire face structure 782 may optionally be plated with a plating. The plating may, for example, comprise multiple (e.g., two, three, four, or more) layers. The plating may, for example, comprise at least one of nickel and gold. The plating may, for example, comprise an (inner) gold layer and an (outer) nickel layer on top of the gold layer. The nickel layer may, for example, have a thickness (e.g., an average thickness) of 0.5 μm to 10 μm, e.g., 2 to 4 μm, e.g., at least essentially 3 μm. The gold layer may, for example, have a thickness (e.g., an average thickness) of 0.5 μm to 5 μm, e.g., 1 μm to 3 μm, e.g., at least essentially 1.5 μm gold. The nickel layer realizes, for example, a barrier metal, which improves wear resistance.

The face structure 782 can act as a connector saver for preventing or reducing contact damages when the first waveguide flange 720 is connected to another waveguide and may provide a reliable interconnect for a large number of cycles (e.g., more than one million cycles). The connector saver can be exchanged upon excessive damage. This avoids changing the antenna device 700 or waveguide connected thereto which generally are the more expensive components.

Furthermore, no use of any special plating on the antenna device 700 or the waveguide connected thereto is needed, which helps to reduce costs (e.g. since plating the small face structure it typically cheaper than plating the large antenna structure).

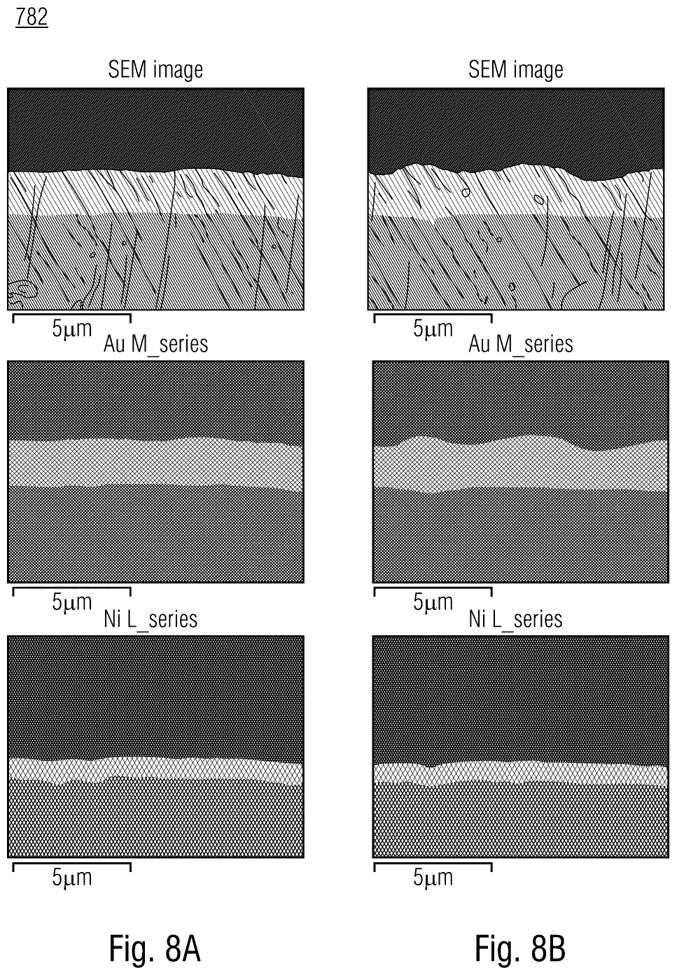

FIG. 8A shows show a cross section captured by scanning electron microscopy (SEM) of the plating of the face structure 782 before being used in repeated mating cycles.

FIG. 8B shows a cross section captured by (SEM) of the plating of the face structure 782 after being used in over one million mating cycles.

In FIGS. 8A, B respectively, the top image shows a conventional SEM image, the middle image shows a gold region detected by energy-dispersive X-ray spectroscopy (EDS), and the bottom image shows a nickel region detected by EDS. Measurements of the thickness of the gold and nickel layer in the SEM image yield, for a new plating, a thickness of 1.9 μm to 2.2 μm for the gold layer and 0.8 μm to 0.9 μm for the nickel layer. After one million mating cycles, the measurement in the SEM image yield a thickness of 1.5 μm to 2.4 μm for the gold layer and a thickness of 0.8 μm to 0.9 μm for the nickel layer.

As can be seen in FIGS. 8A, B, the plating of the face structure 782 has a layer of gold and nickel that are essentially intact and separated after more than one million mating cycles. The gold layer appears to vary more in thickness after the mating cycles, but its overall thickness is not significantly smaller. Therefore, the plating may be used for more than one million cycles without a significant degradation of the face structure 782. FIGS. 8A, B demonstrate how the (increased) plating on the removable face structure (e.g., connector saver) surface allows it to survive more than one million cycles with a good gold layer for contact.

The antenna device described herein can be used for any apparatus that uses coupling between an air interface and a waveguide. For example, the antenna device may be used in an automated test equipment. However, other application areas are also feasible, like, for example, an application in a base station, in a radiofrequency calibration device, or the like.

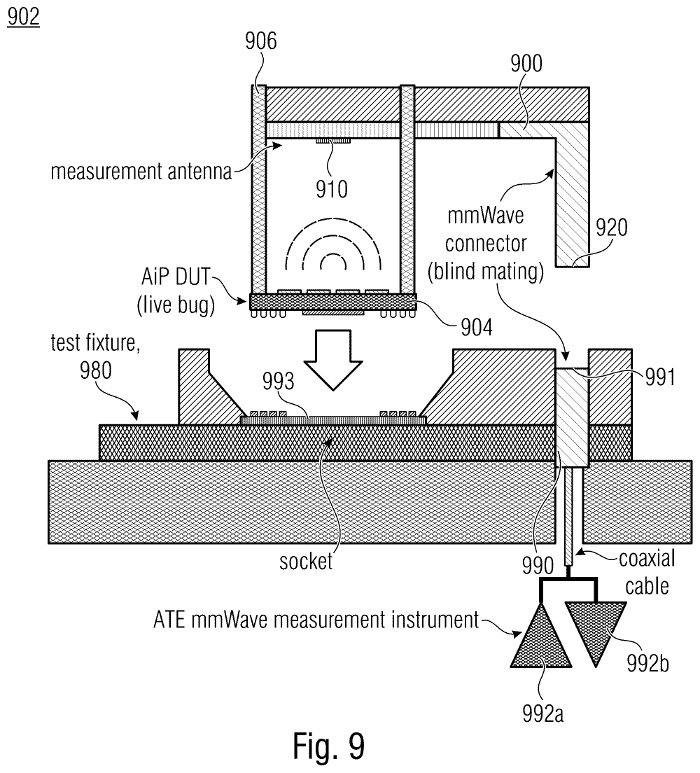

FIG. 9 shows a schematic view of a cross section of an automated test equipment 902.

The automated test equipment (ATE) 902 comprises an antenna device 900 as described herein, and a test fixture 980. The test fixture 980 comprises a second blind mating waveguide flange 991 configured to be coupled to the first waveguide flange 920 of the antenna device 900, wherein the second waveguide flange 991 comprises a ridged waveguide structure that mates with the ridged waveguide structure of the first waveguide flange 920.

The first waveguide flange 920 can be coupled to the second waveguide flange 991, which enables a coupling of an electromagnetic wave between the antenna structure 910 of the antenna device 900 and the second waveguide flange 991, wherein the coupling between the first and second waveguide flanges 920, 991, can be performed easily (due to first blind mating interface) and for many cycles (e.g. due to the use of waveguide flanges, which are comparatively resistant to wear).

Such an ATE 902 can be used to consecutively couple a plurality of devices to be tested with a measurement instrument. The automated test equipment 902 shown in FIG. 9 comprises a signal source 992a and/or a measurement instrument 992b. The signal source 992a is configured to generate electromagnetic waves (e.g. microwave signals), and the measurement instrument 992b is configured to measure/analyse electromagnetic waves (e.g. microwave signals), e.g. in a mm-wave range (e.g., between 1 mm, i.e. 300 GHz, and 10 mm, i.e. 30 GHz, or between 20 GHz and 60 GHz). The measurement instrument 992b may, therefore, be configured to measure electromagnetic waves (signals) of the 5G standard, such as signals in the FR2 bandwidth (or in the FR2 frequency range). Alternatively or additionally, the measurement instrument 992b may be configured to measure in the cm range (e.g., between 3 and 30 GHz) and/or in a sub mm range (e.g., 300 GHz to 1 THz).

The test fixture 980 may comprise a device under test socket 993 configured to electrically couple to a device under test 904. For example, the device under test may be or may comprise at least one of an antenna, an antenna in package (AIP), a radio-frequency integrated circuit (RFIC), a microchip, a printed circuit board, a radio-frequency identification (RFID) chip, a transceiver, a receiver, and a user equipment (e.g., a mobile phone). FIG. 9 shows an example of a device under test socket 993 configured to couple to an AIP device under test 904.

The device under test socket 993 may comprise one or more electrical contacts (e.g., in form of pins) configured to electrically couple to the device under test 904. The device under test socket 993 may be configured to electrically couple to the device under test 904 upon placement of the device under test into the device under test socket 993.

The device under test may, for example, be held in place by being arranged between the device under test socket 993 and the antenna device 900, wherein the antenna device 900 is pressed toward the test fixture (e.g. by a handler) and/or attached to the test fixture (e.g., using clamps). Alternatively or additionally, the antenna device 900 may, for example, comprise a device coupling element 906 (schematically shown in FIG. 9, wherein an actual implementation may vary) configured to hold or engage the device under test 904. The device coupling element 906 may, for example, comprise at least one of a suction aperture (e.g., a suction cup), a magnet, and a clamp. The device coupling element 906 can couple to the device under test 904, e.g. in order to pick up the device under test 904 and to arrange the device under test 904 over, into, or under the device under test socket 993.

The test fixture 980 may have different types of waveguides coupled between the second waveguide flange 991 and the signal source 992a and/or the measurement instrument 992b. For example, the test fixture may comprise a waveguide-to-coaxial transition, to couple the second waveguide flange 991 with the signal source 992a and/or the measurement instrument 992b. Alternatively, the test fixture may comprise a rectangular (e.g., with an oblong rectangular or squared shape) waveguide (or waveguide portion) that terminates at (i.e. is directly coupled with) the second waveguide flange 991. The test fixture 980 may further comprise a coaxial cable coupled to the rectangular waveguide (e.g. via a waveguide to coaxial transition).

The coaxial cable may have a better compatibility with common measurement instruments compared to a rectangular waveguide, and may be more flexible to route, whereas the rectangular waveguide is more compatible with the second waveguide flange 992 and may comprise better electrical characteristics when compared to a coaxial cable (e.g. lower attenuation and better stability of the characteristics). The test fixture 980 therefore improves a compromise between compatibility and efficiency.

It should be noted that the automated test equipment 902 and the test fixture 980 may optionally be supplemented by any of the features, functionalities and details disclosed herein.

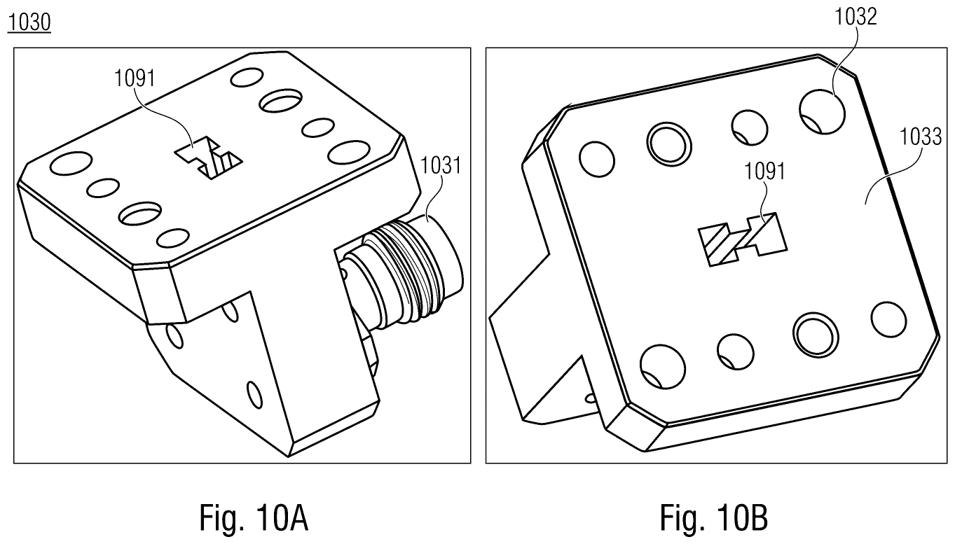

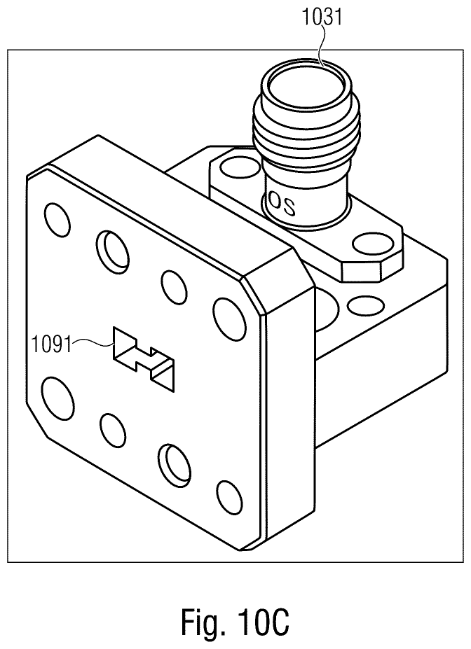

FIG. 10A shows a perspective view of a waveguide-to-coaxial adapter 1030 of the test fixture (wherein the waveguide-to-coaxial adapter may optionally be used in the test fixture 980 of FIG. 9). The waveguide-to-coaxial adapter 1030 comprises the second waveguide flange 1091 (which may, for example, correspond to the second waveguide flange 991) and a coaxial connector 1031 as seen in FIG. 10A. However, the coaxial connector 1031 may be (or comprise) any appropriate type of radio frequency connector which is operable in the desired frequency range. The coaxial connector 1031 may be a male or female connector.

The second waveguide flange 1091 is coupled to the coaxial connector 1031. As a result, the waveguide-to-coaxial adapter 1030 shown in FIG. 10A forms a double ridge waveguide to coaxial adapter that couples electromagnetic waves between the second waveguide flange 1091 and the coaxial connector 1031. The second waveguide flange 1091 shown in FIG. 10A has a double ridge structure. However, the second waveguide flange 1091 may have a different ridged waveguide structure such as a quad-ridged waveguide (e.g., in particular if the first waveguide flange also has a quad-ridged waveguide structure), wherein, for example, the waveguide-to-coaxial adapter may comprises two coaxial connectors to couple in/out two polarizations in the latter case.

FIG. 10B shows a different perspective view of the waveguide-to-coaxial adapter 1030 of FIG. 10A. The second waveguide flange 1091 comprises a (second) blind mating interface 1032. The (second) blind mating interface 1032 of the second waveguide flange may be formed similarly as the (first) blind mating interface of the first blind mating waveguide flange. Therefore, the second blind mating interface 1032 may comprise through holes and/or blind holes, which may, for example, support a self-mating (blind-mating) alignment between the first waveguide flange and the second waveguide flange. Additionally or alternatively, the second blind mating interface 1032 may comprise protrusions, e.g., protrusions integrally formed with or attached to the second face 1033 or formed by a rod inserted (or screwed) into a through or blind hole of the second blind mating interface 1032. The hole and/or protrusion may be a hole and/or protrusion as described above (e.g., with reference to FIGS. 4 to 5D) The first and the second blind mating interface may be complementary. For example, the first blind mating interface may comprise at least one hole configured to receive a protrusion of the second blind mating interface and/or vice versa. In other words, for example, holes and protrusions of the first and second waveguide flange may, for example, be complimentary with respect to each other.

FIG. 10C shows a further different perspective view of the waveguide-to-coaxial adapter 1030 of FIGS. 10A, B. In the example shown in FIG. 10C, the coaxial connector 1031, and consequently an inner conductor (not shown in FIG. 10C) thereof, extend perpendicular to an axis of the waveguide of the second waveguide flange 1091. Furthermore, the inner conductor extends perpendicular to and through the inner side of the waveguide. As a result, the inner conductor extends inside an inner volume of the waveguide, e.g. functioning of a coupling pin. However, alternatively, a coupling loop could also be used.

The waveguide-to-coaxial adapter (e.g., the waveguide-to-coaxial adapter 1030 of FIGS. 10A-C) may comprise a housing with a first and a second housing portion. The first housing portion may comprise a recess, which is also designated as “first housing recess” and the second housing portion may comprise a housing recess, which is also designated as “second housing recess”, wherein the first and second housing recesses form at least a part of the waveguide extending towards the second waveguide flange (or feeding the second waveguide flange).

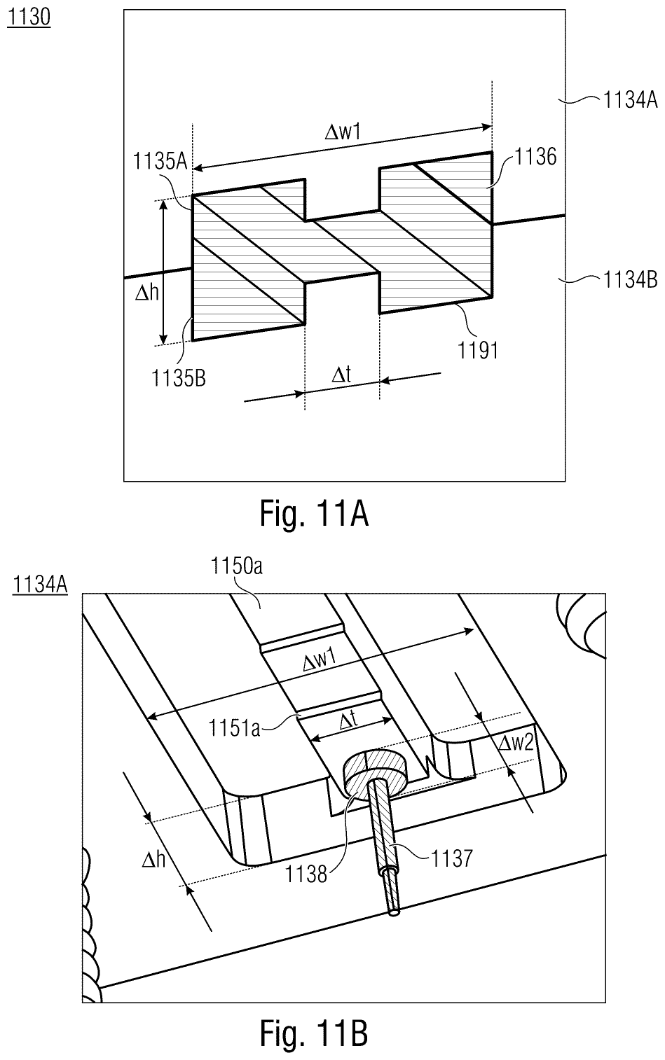

FIG. 11A shows a perspective view of a waveguide-to-coaxial adapter 1130 comprising, for example, a first housing portion 1134A and a second housing portion 1134B. At least one of the first and second housing portions 1134A, B may comprise metal. However, advantageously, both housing portions may be made of metal.

The first housing portion 1134A comprises a first recess 1135A and the second housing portion 1134B comprises a second recess 1135B, wherein the first and second recesses 1135A, B form a (double-ridged) waveguide of the waveguide-to-coaxial adapter, which is also designated as “adapter waveguide” in the following. In the example shown in FIG. 11A, the first and second recesses 1135A, B are dimensioned at least essentially equal (when disregarding a mirrored orientation). In other words, a first surface of the first housing portion 1134A facing and abutting against a (second) surface of the second housing portion 1135A defines an imaginary plane through the waveguide 1136 of the waveguide-to-coaxial adapter, wherein the imaginary plane in the example shown in FIG. 11A sections the waveguide 1136 in the middle.

However, the imaginary plane may be arranged at any other position along the short inner surface of the (adapter) waveguide 1136. For example, the first housing surface may align with the wide inner surface of the (adapter) waveguide 1136 at the side of the first or second housing portion 1134A, B, or may align with a surface of a ridge of the (adapter) waveguide 1136.

The (adapter) waveguide 1136 (and optionally also the second waveguide flange 1191 as seen in FIG. 11A) may have a similar shape as the as the first waveguide flange. For example, the first waveguide flange and second waveguide flange 1136 may both have the dimensions as described with reference to FIG. 2A, such as a width a and Δw1 of 5.49 mm, a height b and Δh of 2.55 mm, and a ridge width a₁ and Δt of 1.37 mm.

FIG. 11B shows a perspective view of the first housing portion 1134A. In this example, the first housing portion 1134A comprises the coaxial connector (not shown) and the inner conductor 1137.

The inner conductor 1137 extends perpendicular to the inner wide side of the (adapter) waveguide 1136. Furthermore, the inner conductor 1137 extends from a first ridge 1150a of the adapter waveguide 1136. The first ridge 1159a (and optionally a second ridge opposite the first ridge 1150a) may comprise a tapering, wherein a height of the first (and/or second) ridge increases in a direction from the second waveguide flange to the inner conductor 1137. For example, the tapering may comprise one, two, three, or more steps 1151a.

The inner conductor 1137 may comprise a conductor ring 1138. The ring may serve as fixation element of the inner conductor 1137 and/or provide further tapering (e.g., in addition to the tapering of the first ridge 1150a).

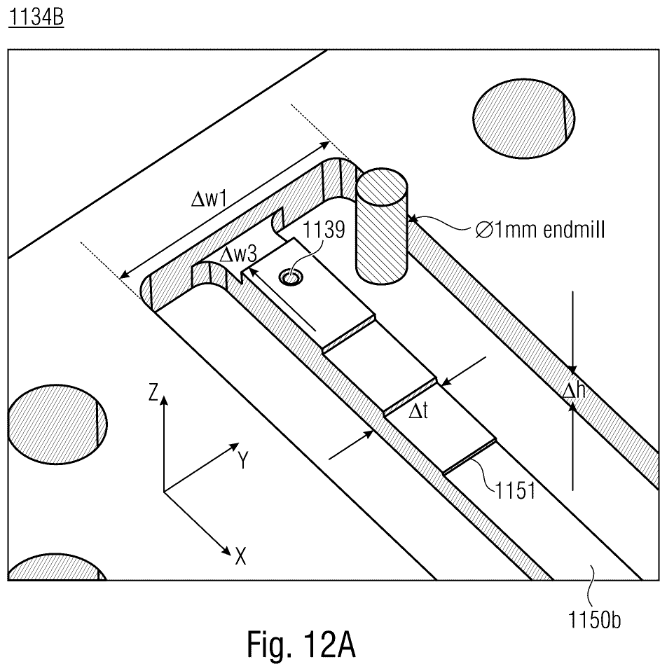

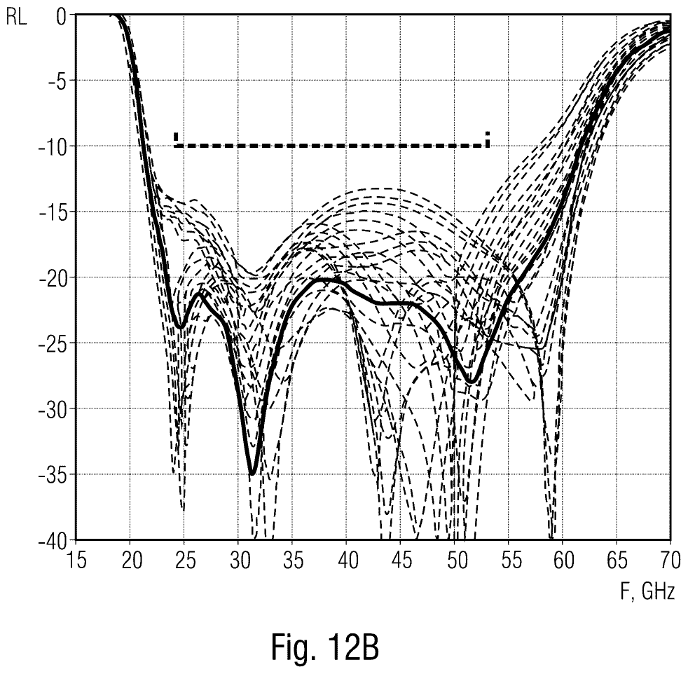

FIG. 12A shows a perspective view of the second housing portion 1134B. The second housing portion 1134B comprises a ridge recess 1139 configured to receive a tip (that is optionally tapered at the end) of the inner connector 1137. As can be seen in FIG. 12A, the second ridge 1150b may also comprise a tapering, e.g., in form of steps 1151b.

The first and second housing recesses 1135A, B can be manufactured, for example, by milling and/or micromachining, which are time and energy efficient manufacturing processes. For example, the first and second housing recesses 1135A, B may be at least partially milled using an end mill with a diameter of at least essentially 1 mm. As a result, the adapter waveguide may have round edges in the dimensions of the end mill.

The dimensions of the adapter waveguide 1136 may, for example, have tolerances of 50p, or 30 μm, or 10 μm. More specifically, the tolerance of the width Δw1 of the (adapter) waveguide 1136 (e.g., width of apertures, launch hole diameter) may be ±0.05 mm. The tolerance of the width of the ridges Δt may be ±0.05 mm. The tolerance of the height Δh of the adapter waveguide may be ±0.05 mm.

FIG. 12B shows a diagram of a simulated return loss (RL) of a waveguide-to-coaxial adapter with under 50 μm manufacturing deviations. It should be noted that, actually, FIG. 12B shows a magnitude of a reflection parameter (in decibels), such that negative decibel values are the result. In a target bandwidth of 24 to 53 GHz, the simulation yields a return loss of more than 20 dB. It is noted that negative and positive values are commonly used to describe return loss, but it is well understood in the field of scattering parameters that the negative and positive values may denote the same return loss. In other words, an engineer skilled in the field of microwave engineering will properly interpret the numbers, irrespective of the actual sign.

It should be noted that the antenna device may also comprise more than one housing portion. For example, the antenna device may comprise a first housing portion comprising the antenna structure and the first waveguide flange and a second housing portion comprising at least a part of a waveguide structure connecting the antenna structure and the first waveguide flange. The first and second housing portions may both comprise recesses, which, when combined, form at least a portion of a waveguide connecting the antenna structure and the first waveguide flange.

Therefore, the description herein related to the first and second housing portions of the waveguide-to-coaxial adapter (including dimensions and tolerances) may, for example, also apply to the antenna device.

Similarly to the first waveguide flange, the second waveguide flange may comprise a second removable face structure that comprises the second face of the second waveguide flange.

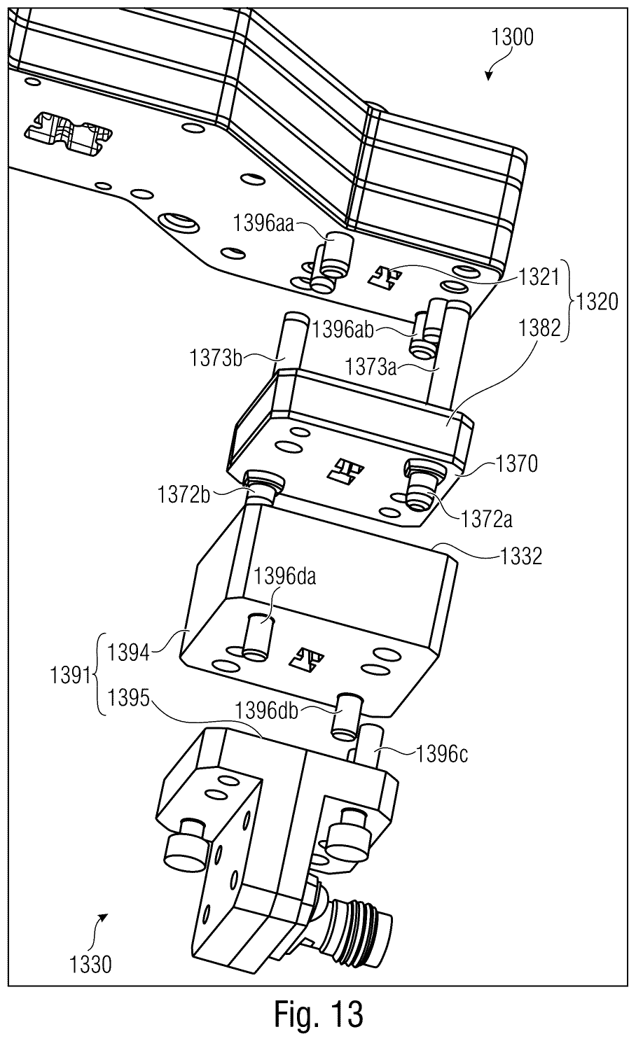

FIG. 13 shows a perspective view of an example of an antenna device 1300 and a waveguide-to-coaxial adapter 1330, wherein the first waveguide flange 1320 comprises a first removable face structure 1382 (for example, as described above) and wherein the second waveguide flange 1391 comprises a second removable face structure 1394 (for example, as described above).

Similarly as described with reference to FIG. 7B, an aperture of a housing of the antenna device 1300 in following will be termed first waveguide base flange 1321 and the first waveguide flange 1320 comprises the first waveguide base flange 1321 and the first removable face structure 1382. Furthermore, an aperture of the (adapter) waveguide facing the second removable face structure 1394 will be termed second waveguide base flange 1395, wherein the second waveguide flange 1391 comprises the second waveguide base flange 1395 and the second removable face structure 1394. However, in absence of its respective removable face structure, the first waveguide base flange 1321 may be used as the first waveguide flange 1320 and the second waveguide base flange 1395 may be used as the second waveguide flange 1391.

The second removable face structure 1394 has a waveguide structure formed therein. The waveguide structures of the first and the second waveguide flanges 1320, 1391 are configured to mate. To this end, the first and second waveguide flanges 1320, 1391 may have at least essentially the same shape (e.g., same dimensions of the waveguide). In particular, the waveguide structures of the first waveguide base flange 1321, of the first removable face structure 1382, of the second removable face structure 134, and of the second waveguide base flange 1395 may have at least essentially the same shape (e.g. in the sense of having the same cross-section of the wave-guiding aperture) (e.g. except for special structures reducing a discontinuity at a transition, like a choke structure). Waveguide portions having at least essentially similar waveguide structures can form a continuous waveguide with essentially no interruption or steps. As a result, unintended reflection of electromagnetic waves can be reduced.

Alternatively, at least one of the first waveguide base flange 1321, the first removable face structure 1382, the second removable face structure 134, and the second waveguide base flange 1395 may have a different shape (e.g. of the wave-guiding aperture). A different shape may, for example, form a step that suppresses transmission of unwanted frequencies (e.g., higher harmonics).

The first removable face structure 1382 comprises (or forms) a first blind mating interface 1370 and the second removable face structure 1394 comprises (or forms) a second blind mating interface 1332. At least one of the first and second blind mating interfaces 1370, 1332 may comprise at least one of a protrusion and a recess. In the example shown in FIG. 13, the first blind mating interface 1370 comprises two protrusions 1372a, b (arranged, for example, in a region of, or in proximity to, opposite corners of the wave-guiding aperture). Furthermore, the second blind mating interface 1332 comprises (at least) two recesses (not shown in FIG. 13) configured to each receive one of the protrusions 1372a, b.

However, the first blind mating interface 1370 may, for example, comprise any other number of protrusions 1372 (e.g., zero, one, three, four, or more protrusions) and the second blind mating interface 1332 may, for example, comprise an equal or higher number of recesses. Alternatively or additionally, the second blind mating interface 1332 may, for example, comprise one or more protrusions and the first blind mating interface 1370 may, for example, comprise an equal or higher number of recesses configured to receive a protrusion of the second blind mating interface 1332.

The first waveguide base flange 1321 may, for example, comprise at least one protrusion received by a recess of the first removable face structure 1382 (e.g., on a surface facing the first waveguide base flange 1321). Alternatively or additionally, the first removable face structure 1382 may comprise at least one protrusion received by a recess of the first waveguide base flange. In the example shown in FIG. 13, the first waveguide base flange 1321 comprises four protrusions received by respective four recesses of the first removable face structure 1382 (in addition to shafts 1373a, b connected to the protrusions 1372a, b).

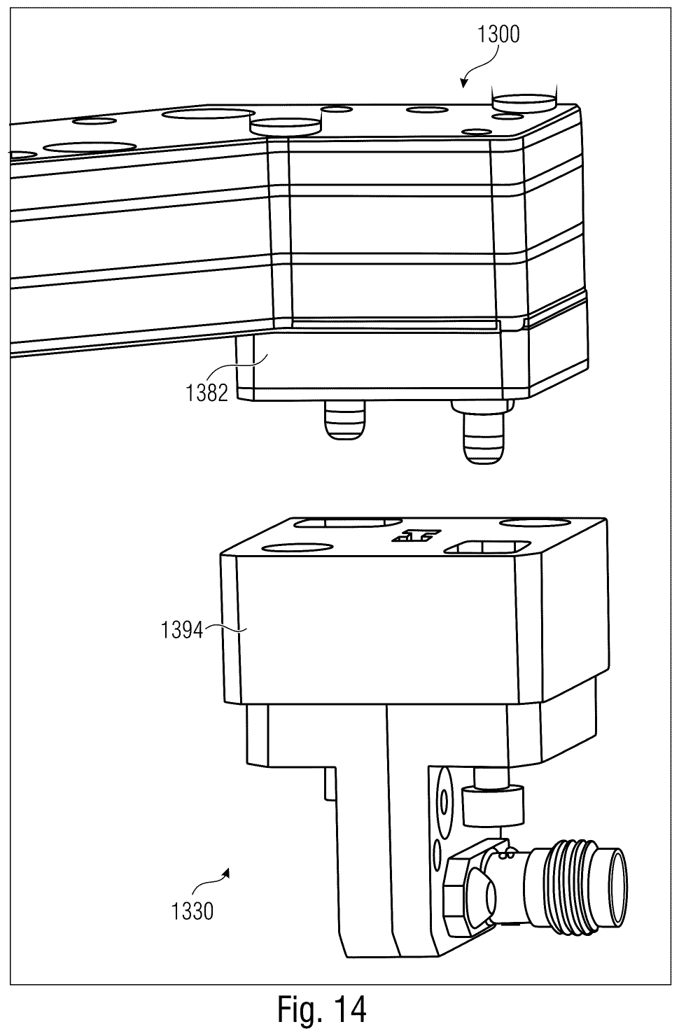

For example, at least one of the protrusions may be (or comprise) a first screw (or bolt) 1396a or a part thereof (e.g., a screw head or screw shaft). The first screw 1396a may, for example, be screwed into a hole (e.g. a through hole) through the housing of the antenna device 1300. The screw may, for example, be inserted into the through hole from a side facing away from the first removable face structure 1382 (i.e. in FIG. 13 from the top), extend through the housing of the antenna device 1300 and exit out of a surface facing the first removable face structure 1382. The screw may be configured to attach the first removable face structure 1382 to the first waveguide base flange 1321. To this end, the first removable face structure 1382 may have one or more threaded holes. In the example shown in FIG. 13, the first waveguide flange 1320 comprises two (first) screws 1396aa,1396ab, wherein heads of the two screws are visible in FIG. 14. However, any other number of (first) screws may be used.

At least one of the protrusions may be integrally formed or may be attached to a surface of the first removable face structure 1382 (and/or second removable face structure 1394). Alternatively, the first removable face structure 1382 may comprise a blind hole or through hole configured to receive a shaft that terminates in the protrusion. In the example shown in FIG. 13, the first removable face structure 1382 comprises two holes that are receiving shafts 1373a, b terminating into the protrusions 1372a, b. The shafts 1373a, b extend through the first removable face structure 1382 and extend further towards the first waveguide base flange 1321 (e.g. in order to ensure a precise alignment). The first waveguide base flange 1321 comprises holes (e.g., in a surface surrounding the aperture of the first waveguide base flange 1321) configured to receive the shafts 1373a,b. The shafts may have a flat surface (e.g. for precise alignment) or may comprise an external thread (forming second screws) configured to be screwed into a threaded hole of at least one of first waveguide base flange 1321 and the first removable face structure 1382.

The second waveguide base flange 1395 comprises through holes (e.g., two or more through holes) configured to receive third screws 1396c extending through a plate of the second waveguide base flange 1395 and received in holes of the second removable face structure 1394. At least one of the second waveguide base flange 1395 and the second removable face structure 1394 may comprise a threaded hole. For example, the second waveguide base flange 1395 may comprise a through hole with a flat inner surface and the second removable face structure 1394 comprises a threaded hole. The third screws 1396c are configured to attach the second removable face structure 1394 to the second waveguide base flange 1395. In the example shown in FIG. 13, the second waveguide flange 1391 comprises two third screws 1396c, but any other number of third screws 1396c may be used.

Alternatively or additionally, the second waveguide flange 1391 may comprise at least one fourth screw 1396d that is inserted into a through hole of the second removable face structure 1394 from a side facing away from the second waveguide base flange 1395 and exits the second removable face structure 1394 at a side facing the second waveguide base flange 1395. In the example shown in FIG. 13, the second waveguide flange 1391 comprises two fourth screws 1396da, 1396db, but any other number of fourth screws 1396d may be used.

FIG. 14 shows a perspective view of the antenna device 1300 and the waveguide-to-coaxial adapter 1330 of FIG. 13, wherein the first removable face structure 1382 is attached to the first waveguide base flange 1321 and the second removable face structure 1394 is attached to the second waveguide base flange 1395. The attachment may be realized using at least one of the first, second, third, and fourth screws 1396a, 1372, 1396c, 1396d. Alternatively or additionally, other fastening elements may be used (e.g., at least one of a clamp, a magnet, and a suction cup).

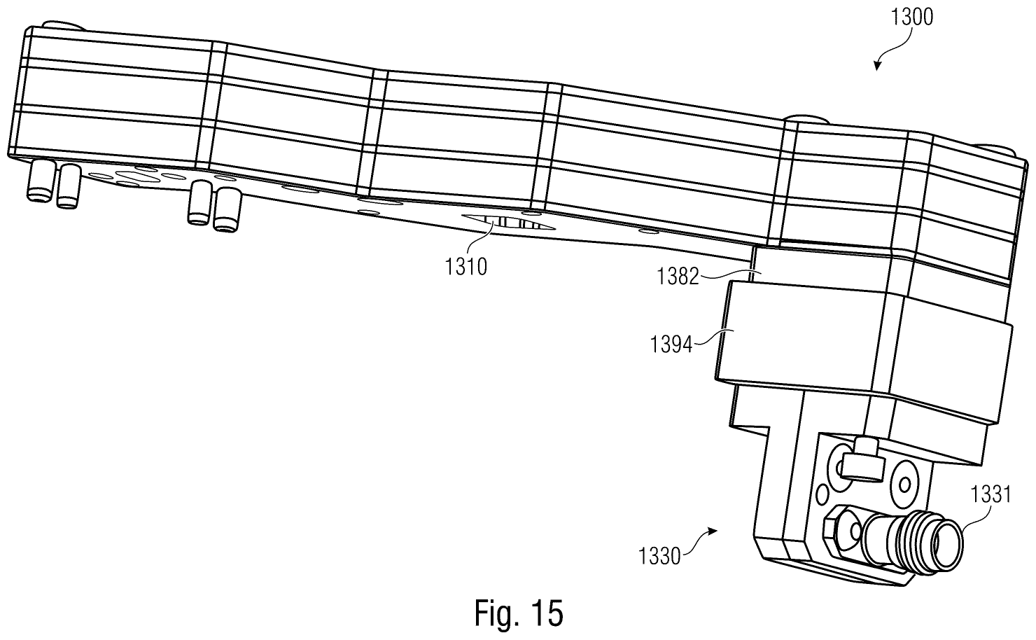

FIG. 15 shows a perspective view of the antenna device 1300 and the waveguide-to-coaxial adapter 1330 of FIGS. 13, 14, wherein the first waveguide flange 1320 is coupled to the second waveguide flange 1391.

The first and second removable face structures 1382, 1394 may be removed and exchanged with a new or refurbished version of the first and second face structures 1382, 1394. The first and second removable face structures 1382, 1394 protect the housing of the antenna device 1300 from wear caused by repeated coupling of the first waveguide flange 1320 to the second waveguide flange 1391.

In the coupled configuration, antenna device 1300 and the waveguide-to-coaxial adapter 1330 form a continuous (or substantially continuous) path for transmission of an electromagnetic signal from the antenna structure 1310 to the coaxial connector 1331 (wherein there may, for example, be some bents included within the signal path, and wherein the transition between the first waveguide flange and the second waveguide flange may naturally comprise some imperfections). As a result, an electromagnetic signal received at the antenna structure 1310 can be transmitted to the coaxial connector 1331 and vice versa.

It should be noted that the antenna device 1300 can comprise more than one first blind mating waveguide flange.

The coaxial connector 1331 can be used for coupling a signal generator and/or a measurement instrument, such as an automated test equipment instrumentation, to the antenna device 1300.

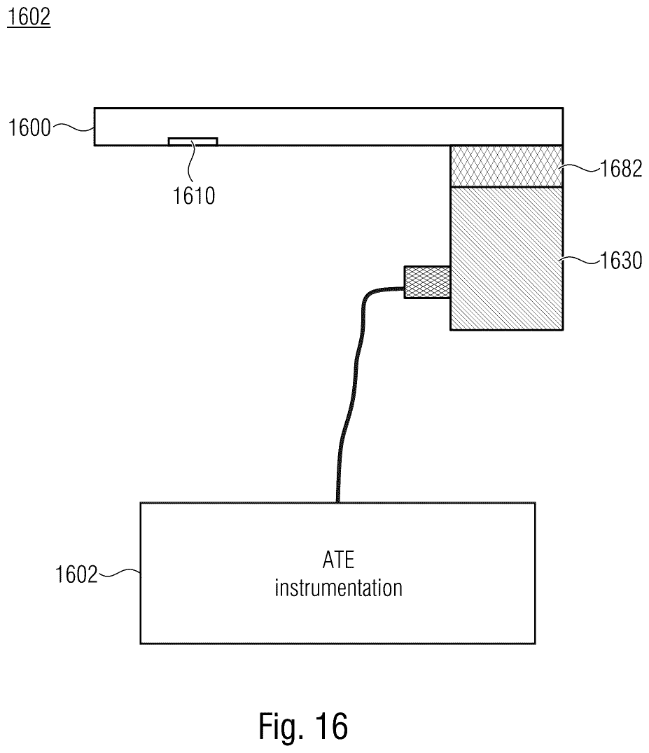

FIG. 16 shows a schematic view of an automated test equipment (ATE) 1602 with the antenna device 1600, the waveguide-to-coaxial adapter 1630, and an ATE instrumentation 1602. The ATE instrumentation 1602 has a coaxial connector (e.g., a female connector) connected (or connectable) to the coaxial connector of the waveguide-to-coaxial adapter 1630. As a result, the ATE instrumentation 1602 is able to at least one of detect, measure, analyse, and process an electromagnetic signal received at the antenna structure 1610. Alternatively or in addition, the ATE instrumentation can provide one or more signals to the antenna structure 1610.

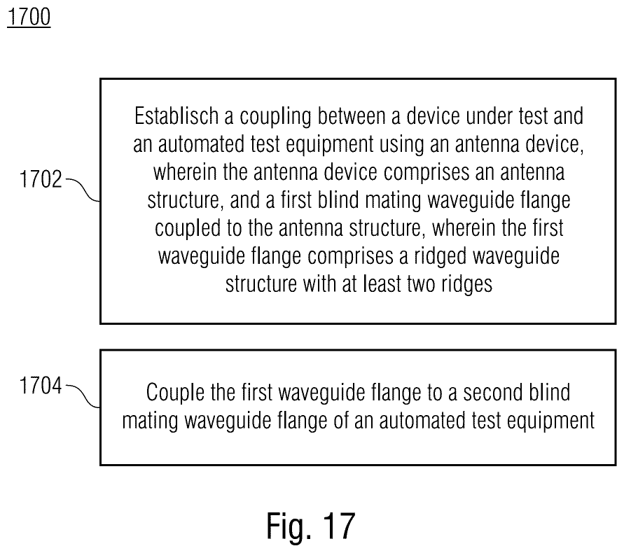

FIG. 17 shows a schematic flow diagram of a method for testing the device under test as described herein.

The method comprises, in step 1702, establishing a coupling between a device under test and an antenna device, wherein the antenna device comprises an antenna structure, and a first blind mating waveguide flange coupled to the antenna structure, wherein the first waveguide flange comprises a ridged waveguide structure with at least two ridges. The method further comprises, in step 1704, coupling the first waveguide flange to a second blind mating waveguide flange of an automated test equipment. It should be noted that steps 1702 and 1704 may be performed substantially simultaneously or in any order.

Establishing a coupling between the device under test and the antenna device may comprise arranging the device under test into a test socket of the automated test equipment.

The method may further comprise electrically coupling the device under test to the test socket of the automated test equipment. The test socket may, for example, be arranged on a test fixture or may be part of a test fixture. Electrically coupling may comprise arranging one or more electrical terminals of the device under test onto pins of the test sockets. It should be noted that electrically coupling the device under test may, for example, be performed before steps 1702 and 1704, or simultaneously with one or both of these steps 1702,1704. For example, the device under test may be pressed into the test socket when the antenna device (i.e. the first waveguide flange) is coupled with the second waveguide flange.

The method may comprise transmitting a signal between the device under test and the automated test equipment at least via the antenna structure, the first waveguide flange, and the second waveguide flange. Transmitting the signal may, for example, comprise causing the device under test to emit an electromagnetic wave, receiving the electromagnetic wave at the antenna structure and transmitting the electromagnetic wave via the first and second waveguide flange to the automated test equipment. The method may comprise generating a control signal that causes the device under test to emit the electromagnetic wave. The method may further comprise generating a measurement signal based on the electromagnetic wave received at the automated test equipment. The method may further comprise processing the measurement signal, which may comprise at least one of filtering, amplifying, storing, and logging the measurement signal or a signal derived therefrom. Alternatively, or in addition, a signal may be provided to the antenna structure, wherein the signal is transmitted to the device under test via the antenna structure. A response of the device under test to the transmitted signal may then be used to derive a test result.

The method may include logging a parameter indicative of a number of coupling processes between the first and second waveguide flange. The method may comprise generating an output that indicates that a threshold number of coupling processes have been completed. The output may include an indication that the first removable face structure needs to be replaced or needs to be replaced soon. The output may include an indication that the second removable face structure needs to be replaced or needs to be replaced soon.

The second waveguide flange may be depressible against a bias in a direction that extends essentially perpendicular to a face of the second waveguide flange, wherein the step of coupling the first waveguide flange to the second waveguide flange may comprise pressing a face of the first waveguide flange onto a face of the second waveguide flange against the bias of the second waveguide flange and attaching the antenna device to the test fixture. The text fixture may comprise one or more clamps configured to engage the antenna device upon pressure applied by the antenna device onto the one or more clamps.

### Implementation Alternatives

Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus.

Depending on certain implementation requirements, embodiments of the invention may be implemented in hardware or in software. The implementation may be performed using a digital storage medium, for example a floppy disk, a DVD, a CD, a ROM, a PROM, an EPROM, an EEPROM or a FLASH memory, having electronically readable control signals stored thereon, which cooperate (or are capable of cooperating) with a programmable computer system such that the respective method is performed.

Some embodiments according to the invention comprise a data carrier having electronically readable control signals, which are capable of cooperating with a programmable computer system, such that one of the methods described herein is performed.

Generally, embodiments of the present invention may be implemented as a computer program product with a program code, the program code being operative for performing one of the methods when the computer program product runs on a computer. The program code may for example be stored on a machine readable carrier.

Other embodiments comprise the computer program for performing one of the methods described herein, stored on a machine readable carrier.

In other words, an embodiment of the inventive method is, therefore, a computer program having a program code for performing one of the methods described herein, when the computer program runs on a computer.

A further embodiment of the inventive methods is, therefore, a data carrier (or a digital storage medium, or a computer-readable medium) comprising, recorded thereon, the computer program for performing one of the methods described herein.

The data carrier, the digital storage medium or the recorded medium are typically tangible and/or non-transitionary.

A further embodiment of the inventive method is, therefore, a data stream or a sequence of signals representing the computer program for performing one of the methods described herein. The data stream or the sequence of signals may for example be configured to be transferred via a data communication connection, for example via the internet.

A further embodiment comprises a processing means, for example a computer, or a programmable logic device, configured to or adapted to perform one of the methods described herein.

A further embodiment comprises a computer having installed thereon the computer program for performing one of the methods described herein.

A further embodiment according to the invention comprises an apparatus or a system configured to transfer (for example, electronically or optically) a computer program for performing one of the methods described herein to a receiver. The receiver may, for example, be a computer, a mobile device, a memory device or the like. The apparatus or system may, for example, comprise a file server for transferring the computer program to the receiver.

In some embodiments, a programmable logic device (for example a field programmable gate array) may be used to perform some or all of the functionalities of the methods described herein. In some embodiments, a field programmable gate array may cooperate with a microprocessor in order to perform one of the methods described herein. Generally, the methods may be performed by any hardware apparatus.

The apparatus described herein may be implemented using a hardware apparatus, or using a computer, or using a combination of a hardware apparatus and a computer.

The apparatus described herein, or any components of the apparatus described herein, may be implemented at least partially in hardware and/or in software.

The methods described herein may be performed using a hardware apparatus, or using a computer, or using a combination of a hardware apparatus and a computer.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

1. An antenna device for establishing a wireless coupling to a device under test, the antenna device comprising
an antenna structure, and
a first blind mating waveguide flange;
wherein the first blind mating waveguide flange is coupled to the antenna structure; and
wherein the first blind mating waveguide flange comprises a ridged waveguide structure with at least two ridges.

2. The antenna device according to claim 1,
wherein a face of the first blind mating waveguide flange comprises a choke structure.

3. The antenna device according to claim 1,
wherein the first blind mating waveguide flange comprises an inner wave-guiding structure;
wherein, at a face of the first blind mating waveguide flange, the inner wave-guiding structure of the first blind mating waveguide flange is surrounded by a recess.

4. The antenna device according to claim 3,
wherein the inner wave-guiding structure of the first blind mating waveguide flange comprises a substantially rectangular cross-section,
wherein two ridges are arranged at two opposite sides of the substantially rectangular cross-section of the inner wave-guiding structure, and
wherein boundaries of the inner wave-guiding structure of the first blind mating waveguide flange comprise coupling recesses in regions of two further sides of the substantially rectangular cross-section of the inner wave-guiding structure,
wherein the coupling recesses are arranged to allow for a coupling between the inner wave-guiding structure of the first blind mating waveguide flange and the recess surrounding the inner wave-guiding structure of the first blind mating waveguide flange.

5. The antenna device according to claim 1,
wherein the first blind mating waveguide flange comprises a removable face structure;
wherein the removable face structure comprises a face of the first blind mating waveguide flange.

6. The antenna device according to claim 5,
wherein the removeable face structure is at least partially plated with a plating that comprises at least one of nickel and gold.

7. The antenna device according to claim 1,
wherein the first blind mating waveguide flange comprises a substantially rectangular cross section with two wide inner surfaces and two narrow inner surfaces,
wherein the two narrow inner surfaces are narrower than the two wide inner surfaces,
wherein a first ridge of the ridged waveguide structure and a second ridge of the ridged waveguide structure extend towards each other from the two wide inner surfaces.

8. The antenna device according to claim 7,
wherein the two narrow inner surfaces comprise a width in a range of 2.4 mm and 2.7 mm,
wherein the two wide inner surfaces comprise a width in a range of 5.3 mm to 5.7 mm,
wherein a width of a gap between the first ridge and the second ridge is in a range between 1.0 mm and 1.2 mm, and
wherein widths of the first ridge and of the second ridge are in a range between 1.3 mm and 1.5 mm.

9. The antenna device according to claim 7,
wherein a ratio between widths of the wide inner surfaces and widths of the narrow inner surfaces is 2.15, with a tolerance of +/−10 percent,
wherein a ratio between the widths of the wide inner surfaces and a width of a gap between the first ridge and the second ridge is 5.04, with a tolerance of +/−10 percent, and
wherein a ratio between the widths of the wide inner surfaces and widths of the first ridge and of the second ridge is 4.01, with a tolerance of +/−10 percent.

10. The antenna device according to claim 1,
wherein the first blind mating waveguide flange comprises a substantially rectangular cross section with four inner surfaces,
wherein the ridged waveguide structure comprises four ridges,
wherein each of the four ridges extends from a respective one of the four inner surfaces towards a central axis of the first blind mating waveguide flange;
wherein the antenna structure is a dual-polarized antenna structure, and
wherein a transition between the ridged waveguide structure and the antenna structure is configured such that a first propagation mode of the ridged waveguide structure couples predominantly with a first polarization of the dual-polarized antenna structure, and
such that a second propagation mode of the ridged waveguide structure couples predominantly with a second polarization of the dual-polarized antenna structure,
wherein the second polarization is different form the first polarization.

11. The antenna device according to claim 10,
wherein the four inner surfaces comprise widths in a range of 5.1 mm and 5.3 mm,
wherein each of the four ridges extends towards a central axis of the ridged waveguide structure in a range of 0.9 mm to 1.1 mm, and
wherein each of the four ridges comprises a width in a range of 1.1 mm to 1.3 mm.

12. An automated test equipment, comprising
the antenna device according to claim 1, and
a test fixture;
wherein the test fixture comprises a second blind mating waveguide flange configured to be coupled to the first blind mating waveguide flange of the antenna device; and
wherein the second blind mating waveguide flange comprises a ridged waveguide structure that mates with the ridged waveguide structure of the first blind mating waveguide flange.

13. The automated test equipment according to claim 12,
wherein the second blind mating waveguide flange is depressible against a bias in a direction that extends essentially perpendicular to a face of the second blind mating waveguide flange.

14. The automated test equipment according to claim 12,
wherein the second blind mating waveguide flange is mounted to be floating;
wherein the test fixture comprises a device under test socket configured to electrically couple to a device under test;
wherein the second blind mating waveguide flange comprises a removable face structure that comprises a face of the second blind mating waveguide flange; and
wherein the removeable face structure is at least partially plated with a plating that comprises at least one of nickel and gold.

15. The automated test equipment according to claim 12,
wherein the second waveguide flange comprises a substantially rectangular cross section with two wide inner surfaces and two narrow inner surfaces,
wherein the narrow inner surfaces are narrower than the wide inner surfaces,
wherein a first ridge of the ridged waveguide structure of the second blind mating waveguide flange and a second ridge of the ridged waveguide structure of the second blind mating waveguide flange extend towards each other from the wide inner surfaces.

16. The automated test equipment according to claim 12,
wherein the second blind mating waveguide flange comprises a substantially rectangular cross section with four inner surfaces,
wherein the ridged waveguide structure of the second blind mating waveguide flange comprises four ridges,
wherein each of the four ridges extends from a respective one of the four inner surfaces towards a central axis of the second blind mating waveguide flange.

17. The automated test equipment according to claim 12, further comprising:
a waveguide-to-coaxial adapter, and
ATE instrumentation;
wherein the waveguide-to-coaxial adapter is coupled to the second blind mating waveguide flange, to establish a connection between the ATE instrumentation and the second blind-mating waveguide flange.

18. A method for testing a device under test, the method comprising:
coupling a first blind mating waveguide flange of an antenna device to a second blind mating waveguide flange of an automated test equipment, and
establishing a coupling between the device under test and the automated test equipment using the antenna device;
wherein the antenna device comprises an antenna structure and the first blind mating waveguide flange coupled to the antenna structure,
wherein the first blind mating waveguide flange comprises a ridged waveguide structure with at least two ridges.

19. The method according to claim 18, further comprising
transmitting a signal between the device under test and the automated test equipment at least via the antenna structure, the first blind mating waveguide flange, and the second blind mating waveguide flange.

20. The method according to claim 18,
wherein the second blind mating waveguide flange is depressible against a bias in a direction that extends essentially perpendicular to a face of the second blind mating waveguide flange,
wherein coupling the first blind mating waveguide flange to the second blind mating waveguide flange comprises
pressing a face of the first blind mating waveguide flange onto a face of the second blind mating waveguide flange against the bias of the second blind mating waveguide flange; and
attaching the antenna device to the test fixture.
